(19) United States
(12) Patent Application Publication
(10) Pub. No.: US 2026/0238184 A1
(43) Pub. Date: Aug. 13, 2026

(54) PIEZOELECTRIC TRENCHES INTERLEAVED WITH ELECTRODES OF A SAW RESONATOR FOR IMPROVED PERFORMANCE

(71) Applicant: Qorvo US, Inc., Greensboro, NC (US)

(72) Inventor: Patrik Rath, Schwaebisch Gmuend (DE)

(21) Appl. No.: 19/475,190

(22) PCT Filed: May 1, 2024
(86) PCT No.: PCT/US2024/027241

§ 371 Date: Oct. 14, 2025

Related U.S. Application Data
(60) Provisional application No. 63/503,017, filed on May 18, 2023.

(51) Int. Cl. H03H 9/145; H03H 3/08; H03H 9/02; H03H 9/25

(52) U.S. Cl. CPC H03H 9/14541; H03H 3/08; H03H 9/02637; H03H 9/25

(57) ABSTRACT

A surface acoustic wave (SAW) resonator device is provided. The SAW resonator device includes a first electrode positioned on an upper surface of a piezoelectric film; a second electrode positioned on the upper surface of the piezoelectric film; and a first piezoelectric trench (PZT) positioned between the first electrode and the second electrode, the first PZT including a recess in the piezoelectric film, the first PZT being of a first trench depth. In some aspects, the piezoelectric trench may alternatively be positioned in the lower surface of the piezoelectric film. In some aspects, the angles of the edges of the piezoelectric trench may be modified as well as the position of the piezoelectric trench relative to the first and second electrodes.

### RELATED APPLICATIONS

The present application claims the benefit of U.S. Provisional Application No. 63/503,017, filed May 18, 2023, which is incorporated herein by reference in its entirety

### TECHNICAL FIELD

The present disclosure relates generally to acoustic wave resonators. In particular, an acoustic wave resonator may include piezoelectric trenches to shift and reduce spurious content to reduce interference and increase signal quality.

### BACKGROUND

An acoustic wave (AW) resonator is a device that uses a piezoelectric material to convert between electrical energy and the mechanical vibrations to filter and process electrical signals. AW resonators are commonly used in electronic communication devices. AW resonators are small, low-cost, and highly reliable resonators used for electronic filters for multiplexers which makes them ideal for use in compact electronic devices.

The use of acoustic wave (SAW) resonators is widespread in communication applications due to several performance advantages, including low insertion loss, high selectivity, and small size. Aspects of acoustic wave (AW) resonators include bulk acoustic wave (BAW) and surface acoustic wave (SAW) resonators. Designing AW filters with low insertion loss, large enough passband width, good out-of-band rejection, and good isolation requires the technology and resonator geometry to be optimized for sufficient coupling, high quality factor, largely suppressing all spurious mode types as well as reducing loss mechanisms in all three dimensions. Following these principles typically enables construction of AW filters with sufficiently high signal quality by minimizing ripples and loss mechanism in the filter response. Unwanted responses can be caused by the same filter or other filters within a multiplexer circuit. passband. Cleaning up resonator responses in a large frequency range is, therefore, an important goal for improvements over existing AW resonator technology.

### SUMMARY

Embodiments of the present disclosure include devices, systems, and methods for piezoelectric trenches (PZTs) between electrodes of SAW resonators for increased performance. Aspects of the disclosure advantageously provide significantly reduced interference between filters of multiplexer circuits. In addition, aspects of the disclosure advantageously allow shifting spurious content of a surface acoustic wave resonator higher on the frequency spectrum as well as shift a fundamental resonance frequency lower on the frequency spectrum which may assist designers of various telecommunications circuitry to avoid interference between resonators or filters of circuits resulting in increased performance.

In an exemplary aspect, a surface acoustic wave (SAW) resonator device is provided. The SAW resonator device includes a first electrode positioned on an upper surface of a piezoelectric film; a second electrode positioned on the upper surface of the piezoelectric film; and a first piezoelectric trench (PZT) positioned between the first electrode and the second electrode, the first PZT including a recess in the piezoelectric film, the first PZT being of a first trench depth.

In one aspect, the first PZT is an upper PZT formed within the upper surface of the piezoelectric film. In one aspect, the first PZT is a lower PZT formed within the lower surface of the piezoelectric film. In one aspect, the first trench depth of the first PZT is within a range of 0% and 100% of a thickness of the piezoelectric film. In one aspect, a trench depth of 100% corresponds to a fully-etched PZT. In one aspect, the first trench depth of the first PZT is within a range of 1 nm and 50 nm. In one aspect, the first PZT is centrally aligned between the first electrode and the second electrode. In one aspect, the piezoelectric film is positioned on or more dielectric layers positioned on a substrate. In one aspect, the first PZT includes a lower width corresponding to the width of the first PZT at the bottom of the PZT and an upper width corresponding to the width of the first PZT at the top of the first PZT. In one aspect, the upper width is greater than the lower width. In one aspect, the first PZT is symmetrical about an axis parallel to the first electrode. In one aspect, first PZT includes a first sloped region corresponding to a first angle and a second sloped region corresponding to a second angle. In one aspect, the SAW resonator device further includes a second PZT positioned within the piezoelectric film on a side of the first electrode opposite the first PZT such that a first piezoelectric plateau of a first width is formed between the first PZT and the second PZT; and a third PZT positioned within the piezoelectric film on a side of the second electrode opposite the first PZT such that a second piezoelectric plateau of a second width is formed between the first PZT and the third PZT. In one aspect, a width of the first electrode is equal to the first width of the first piezoelectric plateau. In one aspect, a width of the first electrode is less than the first width of the first piezoelectric plateau. In one aspect, a width of the first electrode is greater than the first width of the first piezoelectric plateau. In one aspect, the first electrode is centrally aligned with the first plateau. In one aspect, the piezoelectric film is positioned on a Bragg mirror. In one aspect, the piezoelectric film is positioned on a piezoelectric substrate. In one aspect, the piezoelectric film and piezoelectric substrate are made of the same material type and same material orientation. In one aspect, the piezoelectric film is a free-standing piezoelectric membrane. In one aspect, the SAW resonator device is part of a ladder filter. In one aspect, the SAW resonator device is part of a coupled resonator filter.

In some embodiments, the piezoelectric layer has a thickness less than about five times the wavelength lambda of the acoustic wave. In some embodiments, the piezoelectric layer has a thickness between about 5% and about 60% of the wavelength. In some embodiments, the piezoelectric includes/is lithium tantalate. In some embodiments, the piezoelectric is lithium tantalate, with an orientation typically between Y+0° and Y+60° and a propagation along the x-axis of the crystal. In some embodiments, the piezoelectric includes/is lithium niobate. In some embodiments, the piezoelectric is lithium niobate with an orientation typically between Y−20° and Y+60° and a propagation along the x-axis of the crystal.

In an exemplary aspect, a surface acoustic wave (SAW) resonator device is provided. The SAW resonator device includes: a plurality of electrodes positioned on an upper surface of a piezoelectric film of a first thickness; and a plurality of piezoelectric trenches (PZTs) formed within the piezoelectric film between the plurality of electrodes, wherein the plurality of PZTs correspond to regions of the piezoelectric film of a second thickness less than the first thickness.

In one aspect, the plurality of electrodes are spaced from one another by a first pitch and the plurality of PZTs are spaced from one another by a second pitch. In one aspect, the first pitch is different from the second pitch. In one aspect, the plurality of electrodes are spaced from one another by a modulated pitch, such that a first subset of two or more electrodes are spaced from one another by a first pitch and a second subset of two or more interdigital transducers are spaced from one another by a second pitch.

In an exemplary aspect, a method of modifying a surface acoustic wave (SAW) resonator device is provided. The method includes: receiving the SAW resonator device; and applying an ion plasma to the upper surface of the SAW resonator device such that a thickness of one or more interdigital transducers is decreased and piezoelectric trenches are formed between the one or more interdigital transducers.

In an exemplary aspect, a method is provided. The method includes: receiving a surface acoustic wave (SAW) resonator device, the device comprising: a piezoelectric film; an interdigital transducer including a plurality of interleaved electrodes positioned on the piezoelectric film; and a sacrificial layer positioned on the plurality of interleaved electrodes; and applying an ion beam to the upper surface of the SAW resonator device such that the sacrificial layer is removed and forming piezoelectric trenches (PZTs) between the plurality of interleaved electrodes.

In one aspect, the method further includes: patterning the plurality of interleaved electrodes on the piezoelectric film; and patterning the sacrificial layer on the plurality of interleaved electrodes. In one aspect, the interleaved electrodes and sacrificial material are patterned by sputtering, lithography, and dry etching. In one aspect, the interleaved electrodes and sacrificial material are patterned by sputtering, material deposition, and liftoff.

In an exemplary aspect, a method is provided. The method includes: receiving a surface acoustic wave (SAW) resonator device, the device comprising: a piezoelectric film; and an interdigital transducer including a plurality of electrodes; and applying a wet etching procedure to the upper surface of the SAW resonator device such that a thickness of the plurality of electrodes is decreased and one or more piezoelectric trenches (PZTs) are formed between the plurality of electrodes.

In an exemplary aspect, a method is provided. The method includes: receiving a surface acoustic wave (SAW) resonator device, the device comprising: a piezoelectric film; and an interdigital transducer including a plurality of electrodes; and applying a wet etching procedure to the lower surface of the SAW resonator device such that a thickness of the plurality of electrodes is decreased and one or more piezoelectric trenches (PZTs) are formed between the plurality of electrodes.

In one aspect, the piezoelectric film is bonded to a substrate handle using one or more intermediate layers. In one aspect, the method further includes: positioning a first dielectric layer beneath the piezoelectric film; positioning a second dielectric layer is positioned on a top surface of a handle wafer; and bonding the first dielectric layer and the second dielectric layer. In one aspect, the method further includes flattening the bottom surface of the piezoelectric film prior to bonding the first dielectric layer and the second dielectric layer. In one aspect, flattening the bottom surface of the piezoelectric film is performed by wet-etching. In one aspect, flattening the bottom surface of the piezoelectric film is performed by dry-etching. In one aspect, flattening the bottom surface of the piezoelectric film is performed by material removal with an ion plasma. In one aspect, flattening the bottom surface of the piezoelectric film is performed by chemo-mechanical polishing.

Additional aspects, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 is a perspective view of a representative surface acoustic wave (SAW) device, according to aspects of the present disclosure.

FIG. 2 is a cross-sectional side view of a SAW resonator.

FIG. 3 is a cross-sectional side view of a SAW resonator including a piezoelectric trench (PZT), according to aspects of the present disclosure.

FIG. 4 is a comparison of two cross-sectional side views of a SAW resonator with and without piezoelectric trenches, according to aspects of the present disclosure.

FIG. 5A is a graphical representation of the absolute value of the admittance of SAW resonators with and without piezoelectric trenches with fs/fp in a 2.2 GHz frequency range, according to aspects of the present disclosure.

FIG. 5B is a graphical representation of the conductance of SAW resonators with and without piezoelectric trenches with fs/fp in a 2.2 GHz frequency range, according to aspects of the present disclosure.

FIG. 5C is a graphical representation of absolute value of the reflection coefficient of SAW resonators with and without piezoelectric trenches in a 2.2 GHz frequency range, according to aspects of the present disclosure.

FIG. 6A is a graphical representation of the absolute value of the admittance SAW resonators with and without piezoelectric trenches with fs/fp in a 2.2 GHz frequency range, according to aspects of the present disclosure.

FIG. 6B is a graphical representation of the conductance of a SAW resonator without piezoelectric trenches and a SAW resonator with piezoelectric trenches with fs/fp in a 2.2 GHz frequency range, according to aspects of the present disclosure.

FIG. 6C is a graphical representation of the reflection coefficient of a SAW resonator without piezoelectric trenches and a SAW resonator with piezoelectric trenches with fs/fp in the 2.2 GHz frequency range, according to aspects of the present disclosure.

FIG. 7A is a graphical representation of the absolute value of the admittance of a SAW resonator without piezoelectric trenches and a SAW resonator with piezoelectric trenches with fs/fp in the 800 MHz frequency range, according to aspects of the present disclosure.

FIG. 7B is a graphical representation of the conductance of a SAW resonator without piezoelectric trenches and a SAW resonator with piezoelectric trenches with fs/fp in the 800 MHz frequency range, according to aspects of the present disclosure.

FIG. 7C is a graphical representation of the absolute value of the reflection coefficient of a SAW resonator without piezoelectric trenches and a SAW resonator with piezoelectric trenches with fs/fp in the 800 MHz frequency range, according to aspects of the present disclosure.

FIG. 8 is a diagrammatic view of a ladder filter, according to aspects of the present disclosure.

FIG. 9A is a graphical representation of the absolute value of the admittance of a SAW resonator without piezoelectric trenches and a SAW resonator with piezoelectric trenches with fs/fp in the 2.2 GHz frequency range shown in a frequency range far above fs/fp, according to aspects of the present disclosure.

FIG. 9B is a graphical representation of the conductance of a SAW resonator without piezoelectric trenches and a SAW resonator with piezoelectric trenches with fs/fp in the 2.2 GHz frequency range, shown in a frequency range far above fs/fp, according to aspects of the present disclosure.

FIG. 9C is a graphical representation of the absolute value of the reflection coefficient of a SAW resonator without piezoelectric trenches and a SAW resonator with piezoelectric trenches with fs/fp in the 2.2 GHz frequency range, shown in a frequency range far above fs/fp, according to aspects of the present disclosure.

FIG. 10A is a graphical representation of a transmission of a ladder filter including SAW resonators before a trim without PAS procedure and a filter including SAW resonators after a trim without PAS procedure, according to aspects of the present disclosure.

FIG. 10B is a graphical representation of the conductance of a SAW resonator without piezoelectric trenches and a SAW resonator with piezoelectric trenches as used as series resonators for the ladder filter, according to aspects of the present disclosure.

FIG. 10C is a graphical representation of the conductance of a SAW resonator without piezoelectric trenches and a SAW resonator with piezoelectric trenches as used as parallel resonators for the ladder filter, according to aspects of the present disclosure.

FIG. 10D is a graphical representation of the absolute value of the admittance of a SAW resonator without piezoelectric trenches and a SAW resonator with piezoelectric trenches as used as series resonators for the ladder filter, according to aspects of the present disclosure.

FIG. 10E is a graphical representation of the absolute value of the admittance of a SAW resonator without piezoelectric trenches and a SAW resonator with piezoelectric trenches as used as parallel resonators for the ladder filter, according to aspects of the present disclosure.

FIG. 11 is a cross-sectional side view of a SAW resonator with a piezoelectric trench, according to aspects of the present disclosure.

FIG. 12 is a cross-sectional side view of a SAW resonator with an offset piezoelectric trench, according to aspects of the present disclosure.

FIG. 13A is a cross-sectional side view of a SAW resonator with an electrode pitch different from a piezoelectric trench pitch, according to aspects of the present disclosure.

FIG. 13B is a cross-sectional side view of a SAW resonator with varying piezoelectric trench geometries, according to aspects of the present disclosure.

FIG. 14 is a cross-sectional side view of a SAW resonator including a piezoelectric trench and a Bragg mirror, according to aspects of the present disclosure.

FIG. 15 is a cross-sectional side view of a SAW resonator including a piezoelectric trench formed in bulk piezoelectric material, according to aspects of the present disclosure.

FIG. 16 is a cross-sectional side view of a SAW resonator including a piezoelectric trench formed on a freestanding piezoelectric membrane, according to aspects of the present disclosure.

FIG. 17A is a graphical representation of the absolute value of the admittance of SAW resonators with piezoelectric trenches of varying relative depth, according to aspects of the present disclosure.

FIG. 17B is a graphical representation of a conductance of SAW resonators with piezoelectric trenches of varying relative depth, according to aspects of the present disclosure.

FIG. 17C is a graphical representation of a quality factor of SAW resonators with piezoelectric trenches of varying relative depth, according to aspects of the present disclosure.

FIG. 17D is a graphical representation of dissipated power of SAW resonators with piezoelectric trenches of varying relative depth, according to aspects of the present disclosure.

FIG. 18A is a graphical representation of the absolute value of the admittance of SAW resonators with piezoelectric trenches of varying depths normalized to a common resonance frequency, according to aspects of the present disclosure.

FIG. 18B is a graphical representation of a conductance of SAW resonators with piezoelectric trenches of varying depths normalized to a common resonance frequency, according to aspects of the present disclosure.

FIG. 18C is a graphical representation of a quality factor of SAW resonators with piezoelectric trenches of varying depths normalized to a common resonance frequency, according to aspects of the present disclosure.

FIG. 18D is a graphical representation of dissipated power of SAW resonators with piezoelectric trenches of varying depths normalized to a common resonance frequency, according to aspects of the present disclosure.

FIG. 19A is a graphical representation of a comparison of the absolute value of the admittance of SAW resonators with and without piezoelectric trenches, according to aspects of the present disclosure.

FIG. 19B is a graphical representation of a comparison of conductance of SAW resonators with and without piezoelectric trenches, according to aspects of the present disclosure.

FIG. 19C is a graphical representation of a comparison of quality factor of SAW resonators with and without piezoelectric trenches, according to aspects of the present disclosure.

FIG. 19D is a graphical representation of a comparison of dissipated power of SAW resonators with and without piezoelectric trenches, according to aspects of the present disclosure.

FIG. 20A is a graphical representation of a comparison of the absolute value of the admittance of SAW resonators with and without piezoelectric trenches normalized to the resonance frequency, according to aspects of the present disclosure.

FIG. 20B is a graphical representation of a comparison of conductance of SAW resonators with and without piezoelectric trenches normalized to the resonance frequency, according to aspects of the present disclosure.

FIG. 20C is a graphical representation of a comparison of quality factor of SAW resonators with and without piezoelectric trenches normalized to the resonance frequency, according to aspects of the present disclosure.

FIG. 20D is a graphical representation of a comparison of dissipated power of SAW resonators with and without piezoelectric trenches normalized to the resonance frequency, according to aspects of the present disclosure.

FIG. 21A is a graphical representation of a comparison of the absolute value of the admittance of SAW resonators with and without piezoelectric trenches and modulated pitch and duty factor, according to aspects of the present disclosure.

FIG. 21B is a graphical representation of a comparison of conductance of SAW resonators with and without piezoelectric trenches and modulated pitch and duty factor, according to aspects of the present disclosure.

FIG. 21C is a graphical representation of a comparison of quality factor of SAW resonators with and without piezoelectric trenches and modulated pitch and duty factor, according to aspects of the present disclosure.

FIG. 21D is a graphical representation of a comparison of dissipated power of SAW resonators with and without piezoelectric trenches and modulated pitch and duty factor, according to aspects of the present disclosure.

FIG. 22 is a graphical representation of a comparison of the performance of SAW ladder filters and the series and parallel resonators it is made of, based on resonators with and without piezoelectric trenches, according to aspects of the present disclosure.

FIG. 23 is a cross-sectional side view of a SAW resonator with lower piezoelectric trenches, according to aspects of the present disclosure.

FIG. 24A is a graphical representation of the absolute value of the admittance of SAW resonators with piezoelectric trenches of different orientations, according to aspects of the present disclosure.

FIG. 24B is a graphical representation of a conductance of SAW resonators with piezoelectric trenches of different orientations, according to aspects of the present disclosure.

FIG. 24C is a graphical representation of a quality factor of SAW resonators with piezoelectric trenches of different orientations, according to aspects of the present disclosure.

FIG. 24D is a graphical representation of dissipated power of SAW resonators with piezoelectric trenches of different orientations, according to aspects of the present disclosure.

FIG. 25 is a cross-sectional side view of a SAW resonator with lower piezoelectric trenches, according to aspects of the present disclosure.

FIG. 26 is a graphical representation of a relationship between piezoelectric trench depth and SAW resonator performance, according to aspects of the present disclosure.

FIG. 27 is a graphical representation of a relationship between piezoelectric trench depth and SAW resonator performance, according to aspects of the present disclosure.

FIG. 28 is a graphical representation of a relationship between piezoelectric trench depth and SAW resonator performance, according to aspects of the present disclosure.

FIG. 29 is a cross-sectional side view of a SAW resonator with sacrificial layers positioned over electrodes, according to aspects of the present disclosure.

FIG. 30 is a graphical representation of a plot illustrating a relationship between the orientation of the piezoelectric material (cut) and the coupling of the main acoustic mode and of a spurious mode, according to aspects of the present disclosure.

FIG. 31 is a graphical representation of a comparison of performance of SAW devices with piezoelectric trenches on a piezoelectric layer with optimized crystal orientation and on a piezoelectric layer with un-optimized crystal orientation, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

In an exemplary aspect, an AW device includes multiple electrodes. Piezoelectric trenches (PZTs) may be positioned between the electrodes. In some aspects, PZTs may extend partially beneath electrodes. The PZTs may be of any suitable depth, as well as any suitable width. The PZTs may be shaped with sloped edges, called shoulders. These shoulders may be of any suitable slope or angle. The PZTs may be symmetrical or asymmetrical. The width of the PZTs may be the same as the distance between electrodes or less or greater than this distance. In some aspects, PZTs may be of any suitable cross-sectional shape, including a round shape, e.g., a semi-circle, an elliptical shape, or according to any other shape, profile, or pattern. The presence and varying geometries of PZTs between electrodes changes the fundamental frequency of the SAW resonator, the reflectivity and other resonator metric. Particularly it can lead to reduction in velocity, reduction of loss mechanisms and increase in reflectivity. Such increase in reflectivity results in a larger stop band width (SBW) and a larger distance between the series resonance and the upper stop band edge (USBE). The velocity reduction also leads to an increase in velocity contrast to the velocity of any bulk wave related to the underlying substrate. Also, the distance in frequency between main resonance and spurious modes at higher frequencies is largely increased, and the amplitude of higher frequency spurious content is decreased. As the resonator's stop band defines the frequency region where losses due to leakage in propagation direction are avoided, a large stop band width (SBW) may be beneficial. While other measures such as increasing the thickness or optimizing the material type of the electrodes may also affect reflectivity, PZTs have the advantage of avoiding increased mechanical damping which are inherent to metallic layers, but can be very small for piezoelectric materials. Hence, PZTs can achieve higher SBW and higher quality factors while avoiding other typical drawbacks.

Adjustment of these parameters corresponds to adjustment in the presence and amplitude of spurious content such that it may be moved out of the passbands of other filters or eliminated entirely. Aspects of the present disclosure may also include pitch modulation. Both the pitch of the electrodes and the pitch of the PZTs can be modulated. SAW resonators with both pitch modulation and PZTs may result in drastically decreased spurious content both below and above the passband leading to significantly increased performance of SAW resonators. Any of the resonators described herein may be used in a variety of circuits. For example, resonators with piezoelectric trenches or dielectric trenches (described hereafter) may be used as part of a filter, including ladder filters, coupled resonator filters (CRF), or any other suitable filters.

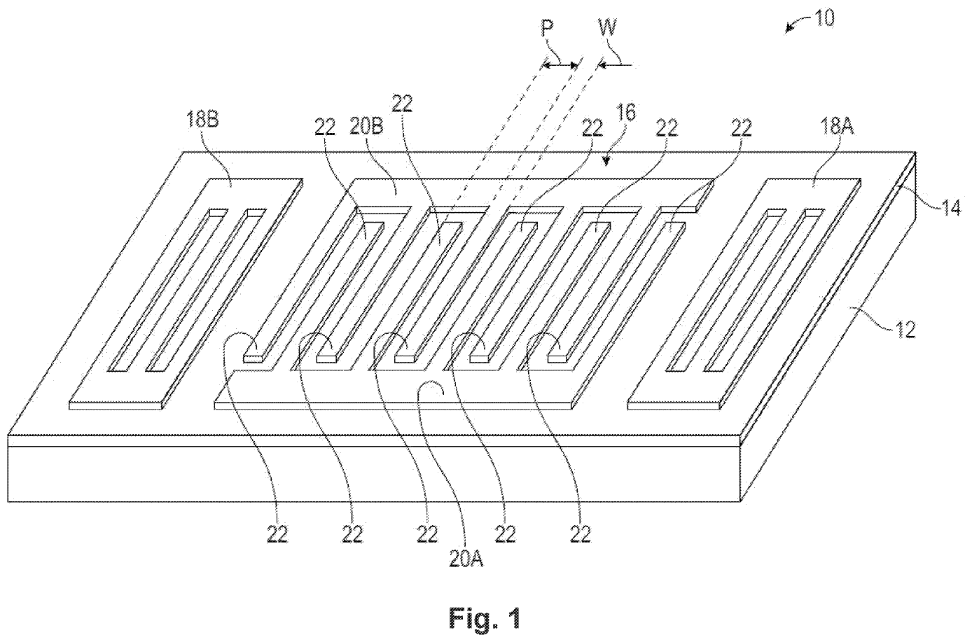

FIG. 1 is a perspective view of a representative surface acoustic wave (SAW) device, according to aspects of the present disclosure. While this disclosure describes principles of the invention in the context of a SAW resonator, it should be understood that the technology presented may be applied to any suitable type of acoustic wave (AW) resonator, including SAW resonators and BAW resonators equally. It particularly can be applied to any AW resonator that employs interdigital transducer electrodes, for various orientations of the acoustic wave propagation and the displacements with respect to the arrangement of the electrodes. The SAW device 10 includes a substrate 12, a piezoelectric layer 14 on the substrate 12, an interdigital transducer (IDT) 16 including electrodes 22 on a surface of the piezoelectric layer 14 opposite the substrate 12, a first reflector structure 18A on the surface of the piezoelectric layer 14 adjacent to the interdigital transducer 16, and a second reflector structure 18B on the surface of the piezoelectric layer 14 adjacent to the interdigital transducer 16 opposite the first reflector structure 18A. In some aspects, an interdigital transducer may also be referred to as an interdigitated transducer. In certain aspects, the substrate 12 may be referred to as a carrier substrate and the overall SAW device 10 may be referred to as a guided SAW device.

The interdigital transducer 16 includes a first electrode 20A and a second electrode 20B, each of which include a number of electrodes 22 that are interleaved with one another as shown. The first electrode 20A and the second electrode 20B may also be referred to as comb electrodes. A lateral distance between adjacent electrodes 22 of the first electrode 20A and the second electrode 20B defines a pitch P between adjacent electrodes 22. The pitch P may at least partially define a resonant frequency of the corresponding electrode(s) 22. In that regard, in embodiments in which the pitch P between electrodes 22 is uniform, all electrodes 22 may be configured to correspond to the same resonant frequency. This resonant frequency may be the resonant frequency of the SAW device 10. A resonant frequency may be the center frequency or primary frequency of mechanical waves generated in the piezoelectric layer 14 by one or more electrodes 22. An electrode width W of the adjacent electrodes 22 together with the pitch P may define a metallization ratio, or duty factor, of electrodes 22.

In operation, an alternating electrical input signal provided at the first electrode 20A is transduced into a mechanical signal in the piezoelectric layer 14, resulting in one or more acoustic waves therein. In the case of the SAW device 10, the resulting acoustic waves are predominately surface acoustic waves. As discussed above, due to the pitch P and the metallization ratio of the interdigital transducer 16, the characteristics of the material of the piezoelectric layer 14, and other factors, the magnitude and frequency of the acoustic waves transduced in the piezoelectric layer 14 are dependent on the frequency of the alternating electrical input signal. This frequency dependence is often described in terms of changes in the impedance and/or a phase shift between the first electrode 20A and the second electrode 20B with respect to the frequency of the alternating electrical input signal. An alternating electrical potential between the two electrodes 20A and 20B creates an electrical field in the piezoelectric material which generates acoustic waves. The acoustic waves travel at the surface and eventually are transferred back into an electrical signal between the electrodes 20A and 20B. The first reflector structure 18A and the second reflector structure 18B reflect the acoustic waves in the piezoelectric layer 14 back towards the interdigital transducer 16 to confine the acoustic waves in the area surrounding the interdigital transducer 16. The substrate 12 may comprise various materials including glass, sapphire, quartz, diamond, silicon (Si), or gallium arsenide (GaAs) among others, with Si being a common choice. The piezoelectric layer 14 may be formed of any suitable piezoelectric material(s). In certain embodiments described herein, the piezoelectric layer 14 is formed of lithium tantalate (LT), or lithium niobate (LiNbO₃ or LN), but is not limited thereto. In certain embodiments, the piezoelectric layer 14 is thick enough or rigid enough to function as a piezoelectric substrate. Accordingly, the substrate 12 in FIG. 1 may be omitted. Those skilled in the art will appreciate that the principles of the present disclosure may apply to other materials for the substrate 12 and the piezoelectric layer 14. The interdigital transducer 16, the first reflector structure 18A, and the second reflector structure 18B may comprise one or more electrically conductive materials, including silver (Au), gold (Ag), tungsten (W), molybdenum (Mo), Nickel (Ni), ruthenium (Ru), iridium (Ir), chromium (Cr), platinum (Pt), titanium (Ti), aluminum (Al), copper (Cu) and alloys thereof as well as alloys with other suitable materials and can be made of either single or multiple layer arrangements, among others. While not shown to avoid obscuring the drawings, additional dielectric layers or any other layers may be provided over all or a portion of the exposed surface of the piezoelectric layer 14, the interdigital transducer 16, the first reflector structure 18A, and the second reflector structure 18B. Such additional passivation layers can form any surface topography, including but not limited to conformal coatings and flat surfaces. Such additional dielectric layers may be provided for passivation, for frequency trimming, for temperature compensation purposes and/or improved thermal conductivity, among other reasons. Suitable materials for such layers include silicon oxide, silicon nitride, titanium oxide, aluminum oxide and can also include dopants such as fluorine. Further, one or more layers may be provided between the substrate 12 and the piezoelectric layer 14 in various embodiments.

In some aspects, a SAW resonator, such as the one shown and described in FIG. 1 may additionally be referred to as an LRT-SAW, multi-layer SAW, thin film SAW, or any other suitable term.

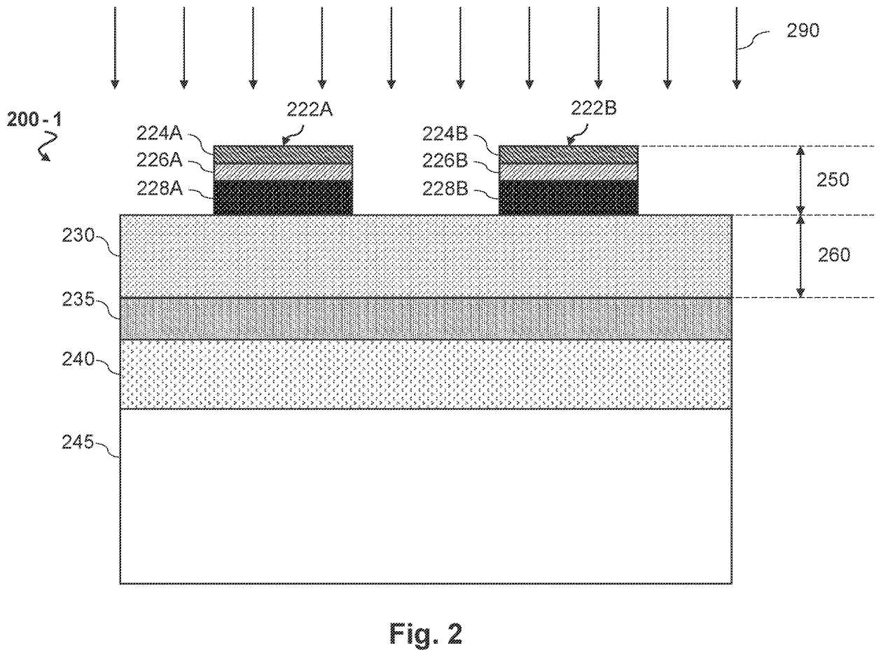

FIG. 2 is a cross-sectional side view of a SAW resonator 200-1. The SAW resonator 200-1 comprises various components including a carrier substrate 245, a dielectric layer 240, a dielectric layer 235, a piezoelectric film 230, and two electrodes 222A and 222B.

The carrier substrate 245 forms the foundation of the SAW resonator 200-1 and provides structural support to the device. It can be made from a variety of materials including glass, silicon, silicon carbide, quartz, diamond, sapphire, or any other suitable material. In certain embodiments, the carrier substrate 245 may be selected based on its mechanical, thermal, or electrical properties to meet the requirements of a specific application.

The dielectric layer 240 is positioned on top of the carrier substrate 245 and provides electrical insulation between the carrier substrate 245 and the rest of the SAW resonator 200-1. In some aspects, the dielectric layer 240 may additionally provide a velocity contrast to the piezoelectric layer to help with guiding the wave localized mainly in the piezoelectric layer. The dielectric layer 240 may additionally help to avoid losses due to overlap with the carrier material as well as reduce TCF. The dielectric layer 240 may be made from a variety of materials including silicon dioxide, silicon oxide, silicon nitride, or aluminum oxide, or any other material, depending on the requirements of the specific application.

In some aspects, the dielectric layer 240 may alternatively be a trap rich layer (TRL). A TRL may, for example, be silicon-based such as poly-crystalline silicon or an implanted layer close to the top surface of the carrier wafer itself.

The dielectric layer 235 is positioned on top of the dielectric layer 240 and serves as a second layer of electrical insulation. It can also be made from a variety of materials including any of those described with reference to layer 240. In some aspects, a resonator may include any suitable number of dielectric layers in any suitable arrangement.

The piezoelectric film 230 is positioned on top of the dielectric layer 235 and transduces electrical energy into mechanical energy. The piezoelectric film 230 can be made from a variety of materials including lithium tantalate, lithium niobate, zinc oxide, aluminum nitride, scandium aluminum nitride, or any other materials. In operation, the piezoelectric film 230 is excited by the electrodes 222A and 222B to produce acoustic waves. A common choice for the piezoelectric layer may be of a thickness less than five times the wavelength lambda of the acoustic wave. Often it is advantageous to have thickness of less than one wavelength and could be between about 5% and about 60% of the wavelength, while the invention disclosed here is not limited to these examples. A common choice for the piezoelectric material may be lithium tantalate, with an orientation typically between about Y+0° and about Y+60° and a propagation along the x-axis of the crystal. Orientations close to about 42° Y-X LT are a common choice, while orientations close to about 30° Y-X LT can in some cases lead to minimized excitation of Rayleigh-type spurious acoustic modes. Another common choice for the piezoelectric material may be lithium niobate, with an orientation typically between about Y−20° and about Y+60° and a propagation along the x-axis of the crystal. A large coupling coefficient can be obtained. In these piezoelectric layers, the devices primarily excite waves with shear horizontal displacements, while the invention disclosed here is not limited to optimization concerning this wave type.

The electrodes 222A and 222B are positioned on top of the piezoelectric film 230 and excite the piezoelectric film 230. The transducers 222A and 222B are transducers within a series of alternating and/or interleaved fingers (see, for example, electrodes 22 of FIG. 1). In operation, one of the transducers 222A or 222B may be connected to a positive electrical potential while the other is connected to a negative potential, resulting in the production of acoustic waves in the piezoelectric film 230. The transducers 222A and 222B can be made from a variety of materials including any of those described herein, depending on the requirements of the specific application.

In some aspects, the electrodes 222 may include multiple layers. For example, the electrode 222A may include a layer 224A, a layer 226A, and a layer 228A. Similarly, the electrode 222B may include a layer 224B, a layer 226B, and a layer 228B. In some aspects, the layers 228A and 228B may facilitate adhesion to the wafer, to avoid migration of atoms (into the substrate and along the surface) and to lead to suitable crystallinity of the layers above. The layers 226A and 226B may be constructed of an electrical conductor (e.g., copper or aluminum). The layers 226A and 226B may ensure a small resistance and low electric losses in the IDT fingers. In some aspects, the layers 224A and 224B may provide adhesion of additional metal layers (e.g., underbump metals for routing) and may help to prevent oxidation and degradation of the layers below. In some aspects, the electrodes 222 may include additional barrier layers or stacks of layers for the similar purposes including to lower sheet resistance, lower mechanical damping, or increased robustness to withstand environmental conditions such as moisture or excitation under high power.

While the SAW resonator 200-1 in FIG. 2 is illustrated as having only two electrodes 222A and 222B, it should be understood that the device may include additional transducers. The number of electrodes may be determined by the specific application and the desired performance characteristics of the SAW resonator 200-1. In certain aspects, additional electrodes may be used to modify various characteristics of the SAW resonator 200-1. The materials used to construct the additional transducers may be the same or different from those used for the initial electrodes.

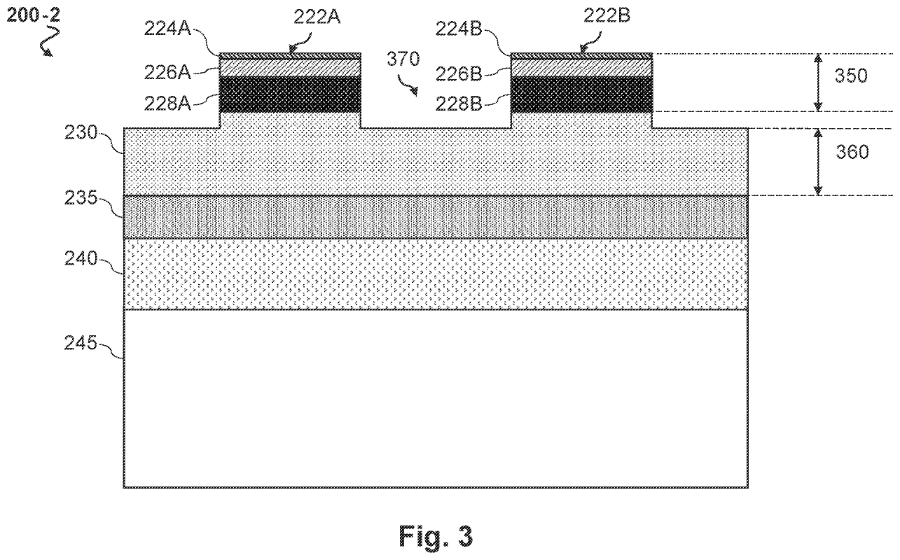

FIG. 3 shows a cross-sectional side view of a SAW resonator 200-2 including a piezoelectric trench (PZT), according to aspects of the present disclosure. In some aspects, the SAW resonator 200-2 may be the same device as the SAW resonator 200-1 after a trim without passivation (“trim without PAS”) procedure has been performed. In some aspects, the SAW resonator 200-2 may be a separate device from the SAW resonator 200-1. For example, the SAW resonator 200-2 may be manufactured according to the geometries shown in FIG. 3.

In some aspects, a trim without PAS procedure includes removing material from the SAW resonator 200-1 with an ion beam. The ion beam may be a beam of charged particles, such as ions, that are accelerated and focused to areas of a resonator using lithography techniques. The ion beam can be scanned across the surface of the resonator to selectively remove material.

In some aspects, a trim without PAS procedure may increase reflectivity of a SAW resonator as well extend the stop band of the resonator. In some aspects, a trim without PAS procedure may additionally decrease the fundamental resonance frequency of the SAW resonator. In some aspects, a trim without PAS procedure may have a minor impact on other properties of the SAW resonator, such as the interaction of the resonator with other resonators of a filter, such as a ladder filter, as well as changes in the capacitance of the resonator.

It should be noted that by varying the angle of the ion beam, the shape of the resonator can be altered. Additionally, a trim without PAS procedure can also be applied to the reflectors 18A and 18B of the SAW resonator 200. The reflectors 18A and 18B may also be referred to as gratings.

According to one manufacturing process of the SAW resonator 200-2, the resonator may first be designed with a fundamental resonance frequency that is higher than the desired fundamental resonance frequency. For example, the SAW resonator 200-2 may initially be substantially similar to the SAW resonator 200-1 shown in FIG. 2. In some aspects, a trim without PAS procedure may be performed on the SAW resonator 200-2. The geometry of the SAW resonator 200-2 may be a resulting cross-sectional shape of the SAW resonator 200-2. In that regard, the fundamental resonance frequency may be shifted downward by the trim without PAS procedure to the desired fundamental resonance frequency. By adjusting the properties of the ion beam and the scan parameters during the trim without PAS procedure, the fundamental resonance frequency can be precisely controlled to achieve the desired frequency.

As shown in FIG. 3, the trim without PAS procedure may form a piezoelectric trench (PZT) 370. A PZT may be a recessed region of a piezoelectric film between electrodes. In the example of FIG. 3, the PZT 370 may be between the electrodes 222A and 222B. The PZT 370 may be formed within the piezoelectric film 230 and may be a region of decreased thickness compared to regions of the piezoelectric film 230 beneath the electrodes 222A and 222B. In that regard, while the piezoelectric film 230 beneath the electrodes 222A and 222B may be of a thickness 260, the piezoelectric film 230 along PZTs, such as the PZT 370 may be of a thickness 360.

Similarly, a portion of the material of the electrodes 222A and 222B may be removed during a trim without PAS procedure. For example, the thickness of the electrodes 222A and 222B may be a thickness 350, where the thickness 350 is less than the thickness 250. In some aspects, however, the thickness of the electrodes 222A and 222B may be preserved during a trim without PAS procedure. For example, electrodes 222A and 222B may be masked during the trim without PAS procedure so that only portions of the piezoelectric film 230 are removed between the electrodes while the electrodes remain unaffected.

According to an alternative manufacturing process of the SAW resonator 200-2, the piezoelectric film 230 may be modified to form the PZTs, such as the PZT 370 shown in FIG. 3, before electrodes are positioned on the piezoelectric film 230. For example, a hard mask may be positioned over the piezoelectric film 230. The PZTs may then be formed within the piezoelectric film. After the PZTs are formed, the electrodes, such as the electrodes 222A and 222B shown in FIG. 3, may be positioned on the piezoelectric film 230 between the PZTs.

In some aspects, the trim without PAS technique may be used to adjust the fundamental resonance frequency of existing SAW resonators. This allows for greater flexibility in adjusting the frequency of SAW resonators without the need for complex redesigns or additional manufacturing steps. Using a trim without PAS procedure can also be used to adjust resonator frequencies across a wafer to counteract frequency variability due to other process steps.

The amount of material removed from the SAW resonator during the trim without PAS procedure may depend on a number of factors, including the time of exposure to the ion beam, the power of the ion beam, and the gas components used. The intensity of an ion beam refers to the density of charged particles within the beam and is typically measured in units of current density, such as microamps per square centimeter. Increasing the intensity of the ion beam can result in more material being removed from the surface of the piezoelectric layer in a given amount of time. Similarly, the gas components used can affect the efficiency and selectivity of the material removal process, as different gases may react with the surface material in different ways. Overall, the precise parameters of the trim without PAS procedure may be optimized for a given resonator design in order to achieve the desired results with desired impact on the device performance.

As described in the present disclosure, the amount of material removed from the SAW resonator during the trim without PAS procedure may vary depending on a number of factors. The piezoelectric layer may be of any suitable thickness. In some aspects, the thickness of the piezoelectric layer 230 may be between 100 and 1000 nanometers. Any suitable amount of material may be removed during a trim without PAS procedure. In some aspects, more material is removed from the piezoelectric layer than from the electrodes. By controlling the amount of material removed during the trim without PAS procedure, it is possible to fine-tune the performance of the SAW resonator to meet specific design requirements.

The method disclosed herein for trimming SAW resonators can be applied to the whole SAW resonator or just parts of the SAW resonator. The method may be applied to any suitable resonators, such as series resonators or parallel resonators (sometimes referred to as shunt resonators) of a ladder filter, or any other suitable resonators of any suitable filter.

In some aspects, the method can be selectively applied to certain shunt resonators, such as those with the lowest frequency, to achieve desired performance characteristics. Additionally, the method can be applied to resonators close to ports, such as the antenna port, receive port, or transmit port, which have the largest impact on performance. This allows for more precise tuning of the SAW resonator to optimize its performance.

To selectively apply the method to specific parts of the SAW resonator, the desired area can be covered with a mask to protect it from exposure to the ion beam. This allows for greater flexibility and precision in the trimming process. Additionally, the method can be applied to any part of the SAW resonator.

In some aspects, the selective application of the trimming process can be used to modify the properties of individual resonators in a filter. For example, in a multi-resonator filter, each resonator can be selectively trimmed to achieve desired frequency responses. This allows for the creation of customized filters with specific performance characteristics. The same applies to coupled-resonator-filters (CRFs) and related geometries and any subset of electrodes and electrode-portions, which such SAW devices are made of.

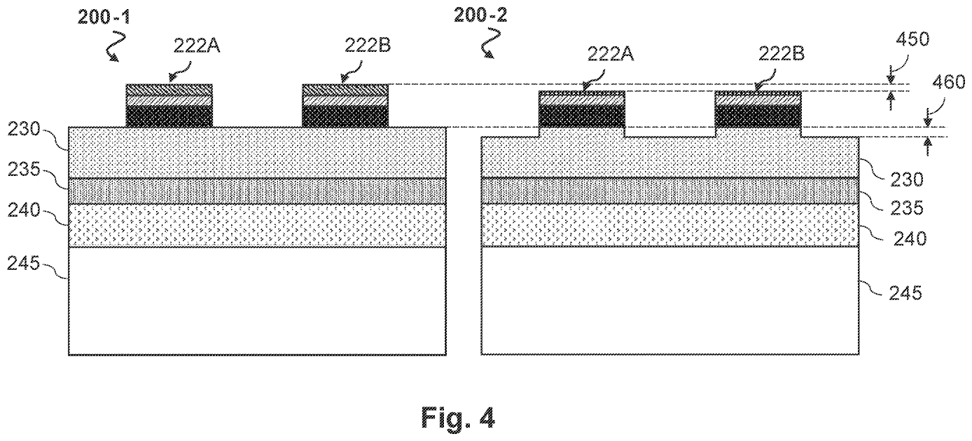

FIG. 4 of the present disclosure shows a comparison between the SAW resonator 200-1 and the SAW resonator 200-2. As depicted in FIG. 4, the SAW resonator 200-1 is shown on the left, while the SAW resonator 200-2 is shown on the right. It can be observed that the electrodes 222A and 222B of the SAW resonator 200-1 are thicker than those of the SAW resonator 200-2. The thickness difference between the electrodes of both resonators is represented by the distance 450 in FIG. 4. This thickness reduction of electrodes in the SAW resonator 200-2 is due to the trim without PAS procedure performed on the resonator.

Additionally, FIG. 4 illustrates that the piezoelectric film 230 between the electrodes 222A and 222B of the SAW resonator 200-1 is thicker than the piezoelectric film 230 between the electrodes of the SAW resonator 200-2. The difference in the thickness of the piezoelectric film between the two SAW resonators is represented by the distance 460 in FIG. 4. The distance 460 is greater than the distance 450, indicating that more piezoelectric film was removed than the electrodes during the trim without PAS procedure.

The reduction in the thickness of electrodes and the piezoelectric film of the SAW resonator 200-2, as compared to the SAW resonator 200-1, may result in a frequency shift of the SAW resonator 200-2 after the trim without PAS procedure. This may result in decreasing or increasing the resonance frequency of a SAW resonator depending on the resonator and type of procedure. However, for the purposes of this disclosure, the trim without PAS procedure described may result in a decrease in the resonance frequency of the SAW resonator 200-1. Additionally, the removal of a small amount of piezoelectric film may increase the acoustic reflectivity of the SAW resonator, thus increasing the stop bandwidth of the resonator. These advantages, among others, may be realized through the use of the trim without PAS procedure disclosed herein.

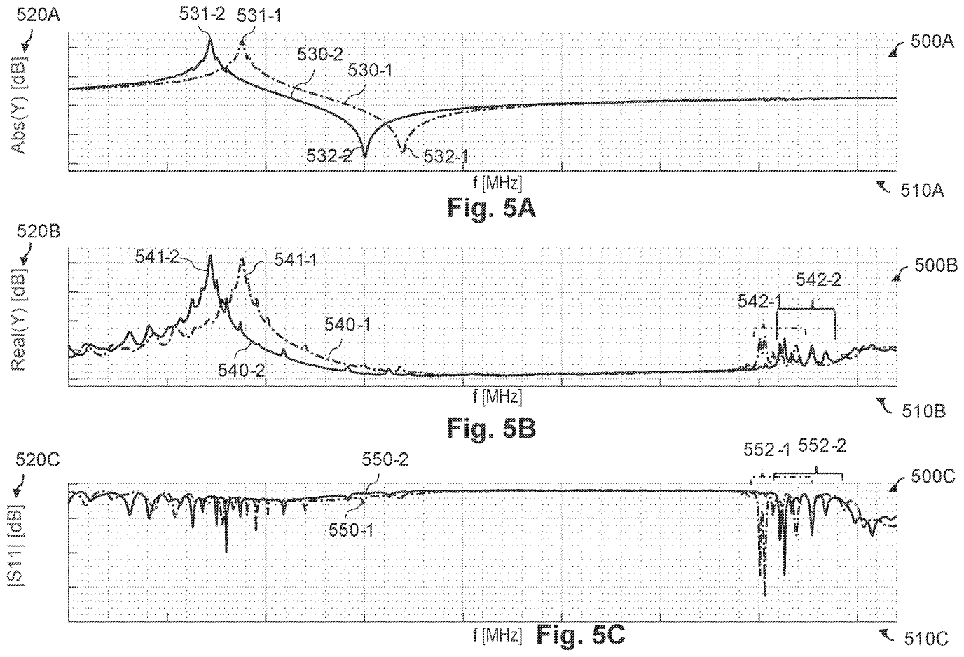

FIG. 5A is a graphical representation of the absolute value of the admittance of a SAW resonator before and after a trim without PAS procedure, according to aspects of the present disclosure. FIG. 5A includes a plot 500A. The plot 500A may include an x-axis 510A corresponding to frequency and a y-axis 520A corresponding to admittance. As shown in the plot 500A, the data set 530-1 represents the frequency response of the SAW resonator before the trim, while the data set 530-2 represents the frequency response of the same SAW resonator after the trim. Both data sets exhibit a resonance frequency 531 and an anti-resonance frequency 532. The resonance frequency 531 represents the frequency at which the SAW resonator has maximum admittance, while the anti-resonance frequency 532 represents the frequency at which the SAW resonator has minimum admittance.

The resonance frequency 531-2 and the anti-resonance frequency 532-2 are shifted lower along the frequency spectrum as compared to the resonance frequency 531-1 and the anti-resonance frequency 532-1. This shift in the frequency spectrum may be caused by removing material from the SAW resonator during the trim without PAS procedure. The material removal results in a change in the thickness of the electrodes and the piezoelectric film between the electrodes, which in turn alters the frequency of the SAW resonator.

It is to be noted that the SAW resonator response before and after the trim without PAS procedure exhibits a similar pattern. The resonance and anti-resonance frequencies of the data set 530-2 are shifted lower than those of the data set 530-1 by a similar amount. The frequency shift may depend on factors such as the type of ion beam used for the trim, the angle of incidence, and the duration of the trim.

The change in the frequency response can be used to optimize the SAW resonator design and improve its performance. The frequency shift can be used to adjust the resonance frequency of the SAW resonator to a desired value. This can be particularly useful in applications such as filters, where a precise frequency response is required.

FIG. 5B is a graphical representation of the conductance of a SAW resonator before and after a trim without PAS procedure, according to aspects of the present disclosure. FIG. 5B includes a plot 500B. The plot 500B may include an x-axis 510B corresponding to frequency and a y-axis 520B corresponding to conductance. As shown in the plot 500B, the data set 540-1 represents the conductance of the SAW resonator before the trim, while the data set 540-2 represents the conductance of the same SAW resonator after the trim. Both data sets show a resonance frequency 541 and spurious content 542. The resonance frequency 541 in both data sets may correspond to the respective resonance frequencies 531 described with reference to FIG. 5A.

Similar to the shift in resonance frequencies described with reference to FIG. 5A, the resonance frequency 541-2 is shifted lower than the resonance frequency 541-1. However, the spurious content 542-2 may be shifted higher along the frequency spectrum than the spurious content 542-1. As shown, this shift lower in the fundamental resonance frequency and shift higher of the spurious content may result in a wider band between these two features. This may advantageously allow the resonator to interfere less with the passband of a filter, such as a ladder filter any other suitable circuit that contains this resonator, as well as interfere less with the performance of filters at common ports.

FIG. 5C is a graphical representation of absolute value of the reflection coefficient of a SAW resonator before and after a trim without PAS procedure, according to aspects of the present disclosure. FIG. 5C includes a plot 500C. The plot 500C may include an x-axis 510C corresponding to frequency and a y-axis 520C corresponding to absolute value of the reflection coefficient. As shown in the plot 500C, the data set 550-1 represents the absolute value of the reflection coefficient of the SAW resonator before the trim, while the data set 550-2 represents the absolute value of the reflection coefficient of the same SAW resonator after the trim. The data set 550-1 shows spurious content 552-1 and the data set 550-2 shows spurious content 552-2. As shown, the spurious content 552-2 is shifted higher along the frequency spectrum than the spurious content 552-1. This shift higher in spurious content may result in shifting spurious content out of the passband region of a filter.

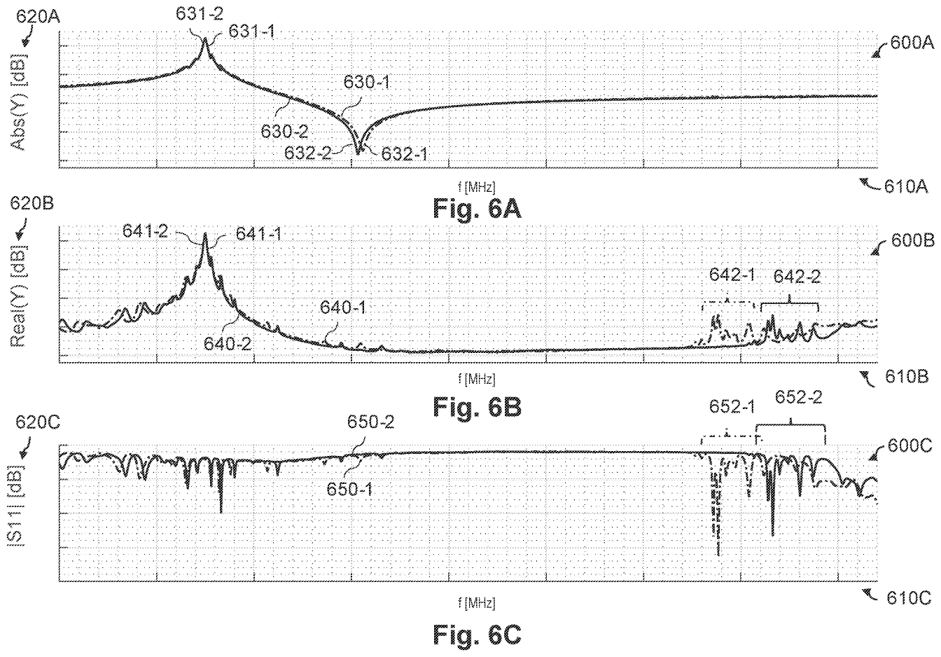

FIGS. 6A-6C may correspond to comparisons of data of a SAW resonator before a trim without PAS procedure and different SAW resonator after a trim without PAS procedure. As shown and described with reference to FIG. 5A above, the trim without PAS procedure shifts the fundamental resonance frequency downward. As a result, for a SAW resonator to operate at the fundamental resonance frequency intended, the resonator must be first manufactured and designed such that the fundamental resonance frequency is higher than desired. The plots shown in FIGS. 6A-6C may correspond to a SAW resonator of a first resonance frequency without a trim without PAS procedure compared to a SAW resonator of the same resonance frequency with a trim without PAS procedure. In that regard, the SAW resonator which is subject to the trim without PAS procedure may initially be of a resonance frequency higher than the first resonance frequency and then exhibit the first resonance frequency after the trim without PAS procedure.

In that regard, FIG. 6A is a graphical representation of the absolute value of the admittance of a SAW resonator before and a SAW resonator after a trim without PAS procedure, according to aspects of the present disclosure. FIG. 6A includes a plot 600A. The plot 600A may include an x-axis 610A corresponding to frequency, and a y-axis 620A corresponding to admittance. As shown in the plot 600A, the data set 630-1 represents the frequency response of a SAW resonator before the trim, while the data set 630-2 represents the frequency response of a different SAW resonator after a trim without PAS procedure. As previously explained, the SAW resonator of the data set 630-2 may be first designed with a fundamental resonance frequency that is higher than the desired fundamental resonance frequency. That fundamental resonance frequency may be adjusted lower during the trim without PAS procedure such that it aligns with the fundamental resonance frequency of the SAW resonator corresponding to the data set 630-1. The data set 630-1 has a resonance frequency 631-1 and an anti-resonance frequency 632-1. The data set 630-2 has a resonance frequency 631-2 and an anti-resonance frequency 632-2. As shown in FIG. 6A, the resonance frequency 631-1 may be aligned with, the same as, or substantially the same as the resonance frequency 631-2. Similarly, the anti-resonance frequency 632-1 may be aligned with, the same as, or substantially the same as the resonance frequency 632-2.

FIG. 6B is a graphical representation of the conductance of a SAW resonator before a trim without PAS procedure and a SAW resonator after a trim without PAS procedure, according to aspects of the present disclosure. FIG. 6B includes a plot 600B. The plot 600B may include an x-axis 610B corresponding to frequency and a y-axis 620B corresponding to conductance. As shown in the plot 600B, the data set 640-1 represents the conductance of a SAW resonator before the trim, while the data set 640-2 represents the conductance of a different SAW resonator after a trim without PAS procedure. Both data sets show a resonance frequency 641 and spurious content 642. The resonance frequency 641 in both data sets may correspond to the respective resonance frequencies 631 described with reference to FIG. 6A.

In some aspects, because the resonator corresponding to the data set 640-2 may be selected with a resonance frequency that is higher than desired which is subsequently lowered during a trim without PAS procedure, the resonance frequency 641-2 may be aligned with, the same as, or substantially the same as the resonance frequency 641-1. However, the spurious content 642-2 may be shifted significantly higher in frequency than the spurious content 642-1. For example, the frequency difference between spurious content 642-2 and 642-1 may be greater than the frequency difference between spurious content 542-2 and 542-1 (referring to FIG. 5B). This increased frequency difference between spurious content 642-2 and 642-1 may advantageously shift the spurious content 642-2 out of the passband of other resonators or filters leading to improved signal quality.

FIG. 6C is a graphical representation of absolute value of the reflection coefficient of a SAW resonator before a trim without PAS procedure and a SAW resonator after a trim without PAS procedure, according to aspects of the present disclosure. FIG. 6C includes a plot 600C. The plot 600C may include an x-axis 610C corresponding to frequency and a y-axis 620C corresponding to absolute value of the reflection coefficient. As shown in the plot 600C, the data set 650-1 represents the absolute value of the reflection coefficient of a SAW resonator before a trim without PAS procedure, while the data set 650-2 represents the absolute value of the reflection coefficient of a different SAW resonator after a trim without PAS procedure. The data set 650-1 shows spurious content 652-1 and the data set 650-2 shows spurious content 652-2. The frequency difference between spurious content 652-2 and 652-1 may be greater than the frequency difference between spurious content 552-2 and 552-1 (referring to FIG. 5C). This increased frequency difference between spurious content 652-2 and 652-1 may advantageously shift the spurious content 652-2 out of the passband of filters leading to improved signal quality.

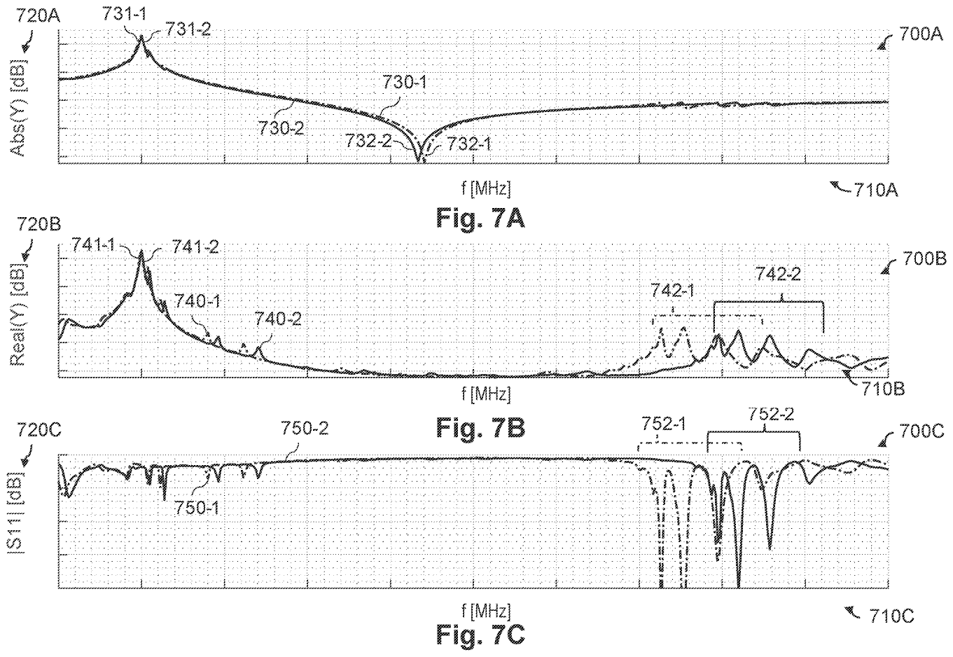

Like FIGS. 6A-6C, FIGS. 7A-7C may correspond to comparisons of data of a SAW resonator before a trim without PAS procedure and different SAW resonator after a trim without PAS procedure. As described with reference to FIGS. 6A-6C, the resonator subject to a trim without PAS procedure may first be selected with a higher than desired resonance frequency which is adjusted downward to the desired frequency, such as to match the unaltered SAW resonator of similar properties. However, as shown in FIGS. 7A-7C, the working frequency range of the SAW resonators corresponding to FIGS. 7A-7C may be substantially lower than the working frequency range of the SAW resonators corresponding to FIGS. 6A-6C. In that regard, the results of a trim without PAS procedure may be applied to SAW resonators of various frequency ranges, including low-band, mid-band, high-band, or any suitable types of SAW resonators.

FIG. 7A is a graphical representation of the absolute value of the admittance of a SAW resonator before a trim without PAS procedure and after a SAW resonator a trim without PAS procedure, according to aspects of the present disclosure. FIG. 7A includes a plot 700A. The plot 700A may include an x-axis 710A corresponding to frequency, and a y-axis 720A corresponding to admittance. As shown in the plot 700A, the data set 730-1 represents the frequency response of a SAW resonator before the trim, while the data set 730-2 represents the frequency response of a different SAW resonator after a trim without PAS procedure. The data set 730-1 has a resonance frequency 731-1 and an anti-resonance frequency 732-1. The data set 730-2 has a resonance frequency 731-2 and an anti-resonance frequency 732-2. As shown in FIG. 7A, the resonance frequency 731-1 may be aligned with, the same as, or substantially the same as the resonance frequency 731-2. Similarly, the anti-resonance frequency 732-1 may be aligned with, the same as, or substantially the same as the resonance frequency 732-2.

FIG. 7B is a graphical representation of the conductance of a SAW resonator before a trim without PAS procedure and a SAW resonator after a trim without PAS procedure, according to aspects of the present disclosure. FIG. 7B includes a plot 700B. The plot 700B may include an x-axis 710B corresponding to frequency and a y-axis 720B corresponding to conductance. As shown in the plot 700B, the data set 740-1 represents the conductance of a SAW resonator before the trim, while the data set 740-2 represents the conductance of a different SAW resonator after a trim without PAS procedure. Both data sets show a resonance frequency 741 and spurious content 742. The resonance frequency 741 in both data sets may correspond to the respective resonance frequencies 731 described with reference to FIG. 7A.

In some aspects, because the resonator corresponding to the data set 740-2 may be selected with a resonance frequency that is higher than desired which is subsequently lowered during a trim without PAS procedure, the resonance frequency 741-2 may be aligned with, the same as, or substantially the same as the resonance frequency 741-1. However, the spurious content 742-2 may be shifted significantly higher in frequency than the spurious content 742-1.

FIG. 7C is a graphical representation of absolute value of the reflection coefficient of a SAW resonator before a trim without PAS procedure and a SAW resonator after a trim without PAS procedure, according to aspects of the present disclosure. FIG. 7C includes a plot 700C. The plot 700C may include an x-axis 710C corresponding to frequency and a y-axis 720C corresponding to absolute value of the reflection coefficient. As shown in the plot 700C, the data set 750-1 represents the absolute value of the reflection coefficient of a SAW resonator before a trim without PAS procedure, while the data set 750-2 represents the absolute value of the reflection coefficient of a different SAW resonator after a trim without PAS procedure. The data set 750-1 shows spurious content 752-1 and the data set 750-2 shows spurious content 752-2. The increased frequency difference between spurious content 752-2 and 752-1 may advantageously extend a passband of the resonator or a filter of the resonator and/or may shift the spurious content 752-2 out of the passband relevant frequency range of other resonators or filters leading to improved signal quality.

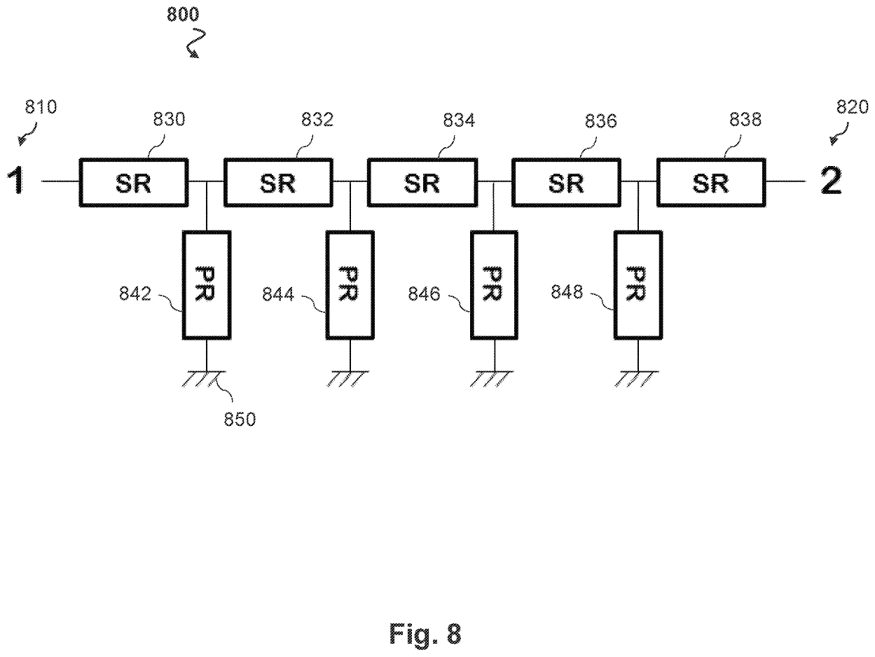

FIG. 8 is a diagrammatic view of a ladder filter 800, according to aspects of the present disclosure. FIG. 8 depicts a ladder filter 800, which is a type of filter commonly used in communication systems. In one embodiment, the ladder filter 800 includes five series resonators in series between a first port 810 and a second port 820. In addition to the series resonators, the ladder filter 800 includes parallel resonators to ground 850 between each series resonator. Other elements, such as inductors or capacitors may be included in the topology, at the ports, in series or parallel with any resonator or at the ground, but are not shown in FIG. 8 for simplicity. The series resonators may include series resonators 830, 832, 834, 836, and 838. Each of the series resonators may be a surface acoustic wave (SAW) resonator, a bulk acoustic wave (BAW) resonator, or any other type of resonator suitable for use in the filter.

The parallel resonators may include parallel resonators 842, 844, 846, and 848. Each of the parallel resonators may be any of the types of resonators listed with reference to series resonators.

The ladder filter 800 may be designed to have a particular frequency response, such as a bandpass filter, a notch filter, a lowpass filter or high pass filter. The resonant frequencies of the series resonators and the parallel resonators may be adjusted to achieve the desired frequency response. In some aspects, the resonant frequencies of any of the series and/or parallel resonators may be adjusted using a trim without PAS process described in the present disclosure. In some aspects, by applying the trim without PAS process spurious frequencies of the ladder filter 800 and/or individual resonators of the ladder filter 800 may be altered so as not to interfere with the performance of other resonators or filters.

In operation, the ladder filter 800 receives a signal at the first port 810 and passes a filtered signal to the second port 820. The filtered signal may be filtered to remove unwanted frequencies or to select specific frequencies of interest. The ladder filter 800 may be used in a variety of applications, such as in cellular communication systems, wireless local area networks (WLANs), GPS or other communication systems.

It is noted, that the trim without PAS procedure may be performed on any suitable SAW resonators of the ladder filter 800. For example, the trim without PAS procedure may be performed on only the series resonator 830. The trim without PAS procedure may be performed on only the series resonator 838. The trim without PAS procedure may be performed on only the parallel resonator 842. The trim without PAS procedure may be performed on only the parallel resonator 848. The trim without PAS procedure may be performed on any other SAW resonator, groups of SAW resonators, or subgroups of SAW resonator according to any pattern or design.

In some aspects, aspects of the present disclosure may include a coupled resonator filter (CRF). A coupled-resonator filter (CRF) may be commonly used in SAW filters and in particular for receive (Rx) filters, as they can be small in size and can provide very good out-of-band rejection. In some aspects, a working principle of a CRF may be based on the interaction of coupling acoustic modes of different IDT sections which sit side-by-side within common reflectors. A main parameter for this acoustic interaction is the reflection coefficient of the underlying unit cell (IDT finger of finite width on a piezoelectric material). The concept of a PZT makes the reflection coefficient tunable by introducing new degrees of freedom. In that regard, the reflection coefficient for different IDT sections or for individual IDT fingers may be varied to enable to better optimize CRF structures and similar geometries which are based on IDT fingers.

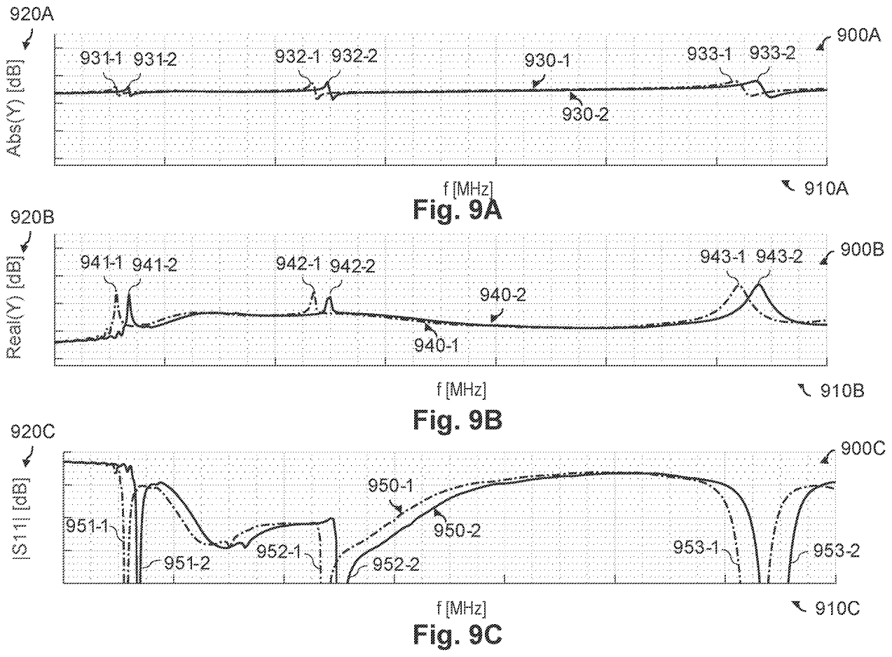

FIG. 9A is a graphical representation of the absolute value of the admittance of a SAW resonator before a trim without PAS procedure and a SAW resonator after a trim without PAS procedure, according to aspects of the present disclosure. FIG. 9A includes a plot 900A. The plot 900A may include an x-axis 910A corresponding to frequency, and a y-axis 920A corresponding to admittance. As shown in the plot 900A, the data set 930-1 represents the frequency response of a SAW resonator before the trim, while the data set 930-2 represents the frequency response of a different SAW resonator after a trim without PAS procedure. The data set 930-1 includes multiple higher order modes. Specifically, the data set 930-1 includes a mode 931-1, a mode 932-1, and a mode 933-1. These higher modes may be caused by plate modes or longitudinal displacement modes of the corresponding SAW resonator or any other suitable types of modes. Similarly, the data set 930-2 includes multiple higher order modes. Specifically, the data set 930-2 includes a mode 931-2, a mode 932-2, and a mode 933-2. As shown, the higher modes 931-2, 932-2, and 933-2 may be shifted higher along the frequency spectrum than the modes 931-1, 932-1, and 933-1. This may be a result of the trim without PAS feature described herein. In that regard, higher modes of a SAW resonator after a trim without PAS feature may be shifted so as to not interfere with other resonators of a filter and/or filters of a circuit.

FIG. 9B is a graphical representation of the conductance of a SAW resonator before a trim without PAS procedure and a SAW resonator after a trim without PAS procedure, according to aspects of the present disclosure. FIG. 9B includes a plot 900B. The plot 900B may include an x-axis 910B corresponding to frequency, and a y-axis 920B corresponding to conductance. As shown in the plot 900B, the data set 940-1 represents the frequency response including higher order modes of a SAW resonator before a trim without PAS procedure, while the data set 940-2 represents the frequency response including higher order modes of a different SAW resonator after a trim without PAS procedure. The data set 940-1 includes multiple higher order modes. Specifically, the data set 940-1 includes a mode 941-1, a mode 942-1, and a mode 943-1. These higher modes may be caused by plate modes or longitudinal displacement modes of the corresponding SAW resonator or any other suitable types of modes. Similarly, the data set 940-2 includes multiple higher order modes. Specifically, the data set 940-2 includes a mode 941-2, a mode 942-2, and a mode 943-2. As shown, the higher modes 941-2, 942-2, and 943-2 may be shifted higher along the frequency spectrum than the modes 941-1, 942-1, and 943-1. This may be a result of the trim without PAS feature described herein. In that regard, higher modes of a SAW resonator after a trim without PAS feature may be shifted so as to not interfere with other resonators of a filter and/or filters of a circuit.

FIG. 9C is a graphical representation of absolute value of the reflection coefficient of a SAW resonator before a trim without PAS procedure and a SAW resonator after a trim without PAS procedure, according to aspects of the present disclosure. FIG. 9C includes a plot 900C. The plot 900C may include an x-axis 910C corresponding to frequency, and a y-axis 920C corresponding to absolute value of the reflection coefficient. As shown in the plot 900C, the data set 950-1 represents the frequency response including higher order modes of a SAW resonator before a trim without PAS procedure, while the data set 950-2 represents the frequency response including higher order modes of a different SAW resonator after a trim without PAS procedure. The data set 950-1 includes multiple higher order modes. Specifically, the data set 950-1 includes a mode 951-1, a mode 952-1, and a mode 953-1. These higher modes may be caused by plate modes or longitudinal displacement modes of the corresponding SAW resonator or any other suitable types of modes. Similarly, the data set 950-2 includes multiple higher order modes. Specifically, the data set 950-2 includes a mode 951-2, a mode 952-2, and a mode 953-2. As shown, the higher modes 951-2, 952-2, and 953-2 may be shifted higher along the frequency spectrum than the modes 951-1, 952-1, and 953-1. This may be a result of the trim without PAS feature described herein. In that regard, higher modes of a SAW resonator after a trim without PAS feature may be shifted so as to not interfere with other resonators of a filter and/or filters of a circuit.

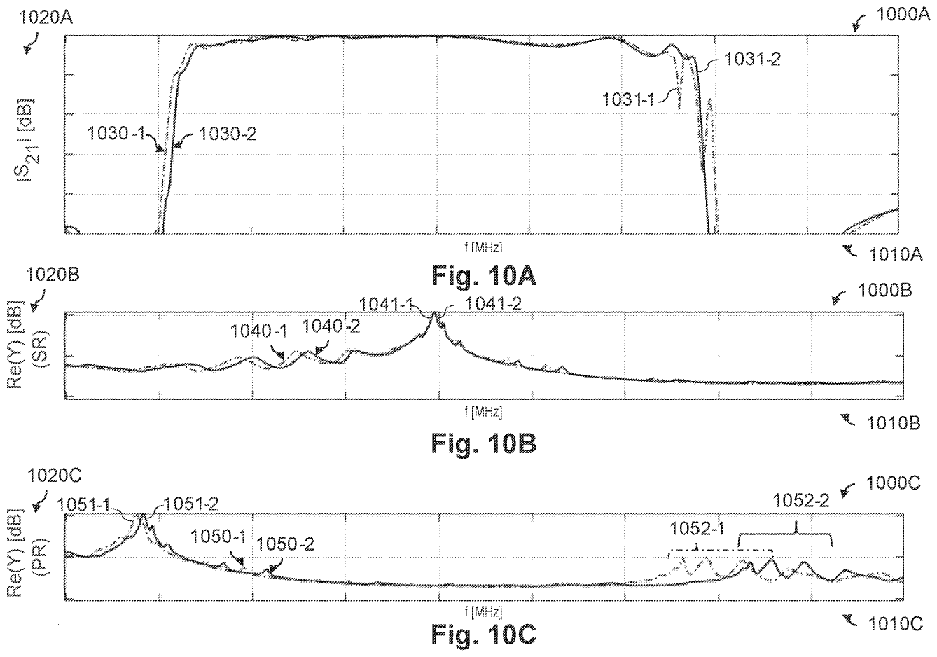

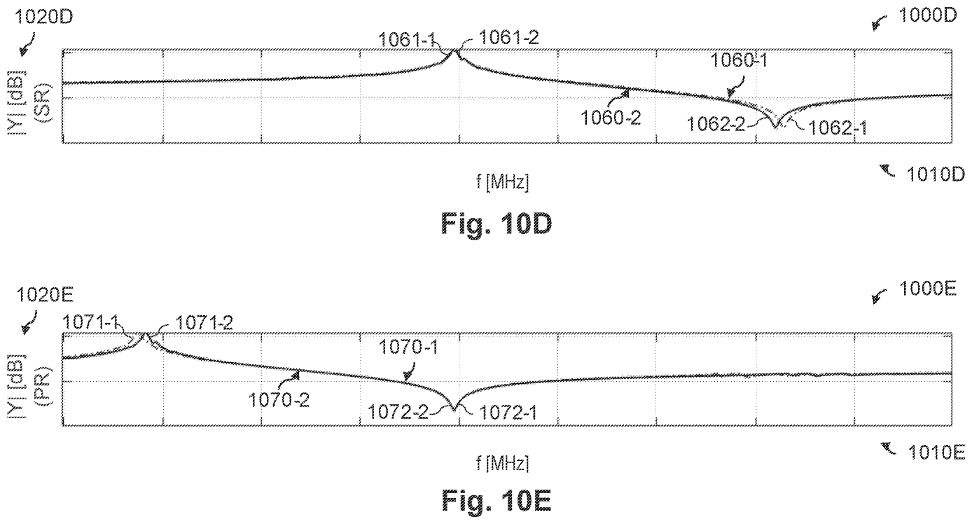

FIG. 10A is a graphical representation of a frequency response of a filter including SAW resonators before a trim without PAS procedure and a filter including SAW resonators after a trim without PAS procedure, according to aspects of the present disclosure. FIG. 10A includes a plot 1000A. The plot 1000A may include an x-axis 1010A corresponding to frequency and a y-axis 1020A corresponding to the transmission of the filter between ports 1 and 2. In some aspects, the plot 1000A may illustrate a frequency response of a ladder filter, such as the ladder filter 800 of FIG. 8. As shown, the plot 1000A includes a data set 1030-1 and a data set 1030-2. In some aspects, the data set 1030-1 may correspond to a frequency response of a ladder filter, such as the ladder filter 800 of FIG. 8, that is not subject to a trim without PAS procedure is performed. The data set 1030-2 may correspond to a frequency response of a ladder filter, such as the ladder filter 800 of FIG. 8 after a trim without PAS procedure is performed. As shown, as a result of the trim without PAS procedure, the passband can be cleaned up from ripples or notches that are caused by spurious responses of the underlying parallel resonators. This is shown in FIG. 10A as notches at the right most 1031-1 fall within the passband while this is not the case for the data set 1030-2.

FIG. 10B is a graphical representation of the conductance of a SAW resonator before a trim without PAS procedure and a SAW resonator after a trim without PAS procedure, according to aspects of the present disclosure. In some aspects, FIG. 10B may correspond to a series resonator (SR). FIG. 10B includes a plot 1000B. The plot 1000B may include an x-axis 1010B corresponding to frequency and a y-axis 1020B corresponding to conductance. As shown in the plot 1000B, the data set 1040-1 represents the conductance of a SAW resonator before the trim, while the data set 1040-2 represents the conductance of a different SAW resonator after a trim without PAS procedure. Both data sets show a resonance frequency 1041. The resonance frequency 1041-2 may be aligned with, the same as, or substantially the same as the resonance frequency 1041-1.

FIG. 10C is a graphical representation of the conductance of a SAW resonator before a trim without PAS procedure and a SAW resonator after a trim without PAS procedure, according to aspects of the present disclosure. In some aspects, FIG. 10C may correspond to a parallel resonator (PR). FIG. 10C includes a plot 1000C. The plot 1000C may include an x-axis 1010C corresponding to frequency and a y-axis 1020C corresponding to conductance. As shown in the plot 1000C, the data set 1050-1 represents the conductance of a SAW resonator before the trim, while the data set 1050-2 represents the conductance of a different SAW resonator after a trim without PAS procedure. Both data sets show a resonance frequency 1051 and spurious content 1052. As described with reference to FIG. 6B and/or FIG. 7B previously, spurious content 1052-2 may be shifted higher along the frequency spectrum than the spurious content 1052-1 as a result of the trim without PAS procedure.

FIG. 10D is a graphical representation of the absolute value of the admittance of a SAW resonator before a trim without PAS procedure and a SAW resonator after a trim without PAS procedure, according to aspects of the present disclosure. FIG. 10D includes a plot 1000D. The plot 1000D may include an x-axis 1010D corresponding to frequency, and a y-axis 1020D corresponding to admittance. As shown in the plot 1000D, the data set 1060-1 represents the frequency response of a SAW resonator before the trim, while the data set 1060-2 represents the frequency response of a different SAW resonator after a trim without PAS procedure. The data set 1060-1 has a resonance frequency 1061-1 and an anti-resonance frequency 1062-1. The data set 1060-2 has a resonance frequency 1061-2 and an anti-resonance frequency 1062-2. As shown in FIG. 10D, the resonance frequency 1061-1 may be aligned with, the same as, or substantially the same as the resonance frequency 1061-2. Similarly, the anti-resonance frequency 1062-1 may be aligned with, the same as, or substantially the same as the resonance frequency 1062-2.

FIG. 10E is a graphical representation of the absolute value of the admittance of a SAW resonator before a trim without PAS procedure and a SAW resonator after a trim without PAS procedure, according to aspects of the present disclosure. FIG. 10E includes a plot 1000E. The plot 1000E may include an x-axis 1010E corresponding to frequency, and a y-axis 1020E corresponding to admittance. As shown in the plot 1000E, the data set 1070-1 represents the frequency response of a SAW resonator before the trim, while the data set 1070-2 represents the frequency response of a different SAW resonator after a trim without PAS procedure. The data set 1070-1 has a resonance frequency 1071-1 and an anti-resonance frequency 1072-1. The data set 1070-2 has a resonance frequency 1071-2 and an anti-resonance frequency 1072-2. As shown in FIG. 10E, the resonance frequency 1071-1 may be aligned with, the same as, or substantially the same as the resonance frequency 1071-2. Similarly, the anti-resonance frequency 1072-1 may be aligned with, the same as, or substantially the same as the resonance frequency 1072-2.

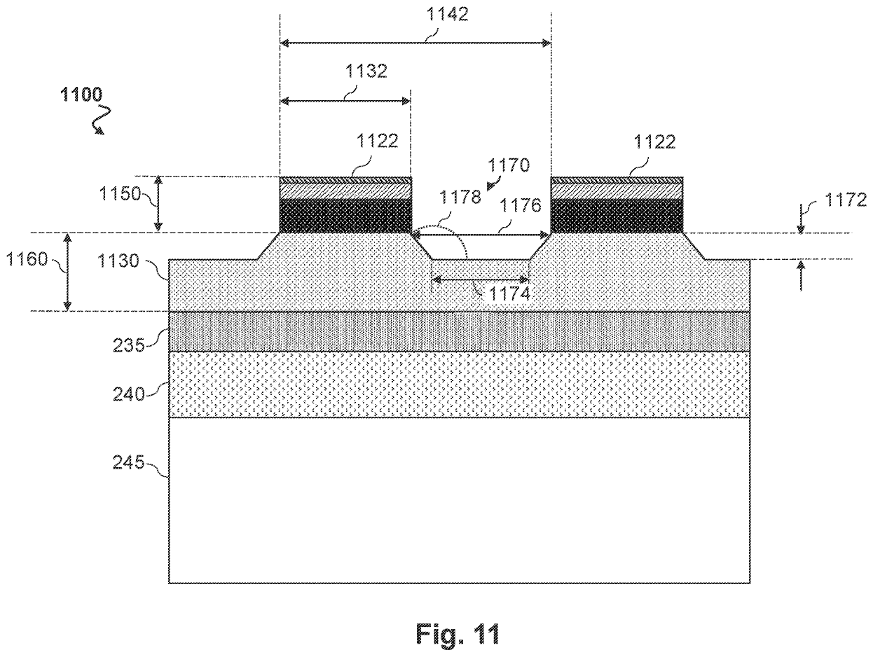

FIG. 11 is a cross-sectional side view of a SAW resonator 1100 with a piezoelectric trench 1170, according to aspects of the present disclosure. As shown in FIG. 11, a PZT may be configured according to any suitable geometry.

The SAW resonator 1100 may be similar to the SAW resonators 200-1 and/or 200-2 described previously with reference to FIGS. 2 and 3. In particular, the SAW resonator 1100 may include a piezoelectric film 1130. The piezoelectric film 1130 may be similar to the piezoelectric film 230 previously described. In some aspects, the piezoelectric film 1130 may be positioned on the layers 235, 240, and 245 as shown in FIG. 11. The SAW resonator 1100 may also include multiple electrodes 1122. The electrodes 1122 may be similar to the electrodes 222A and 222B of FIGS. 2 and 3.

The SAW resonator 1100 includes a PZT 1170. In the example shown in FIG. 11, the PZT 1170 may include tapered edges or shoulders. Specifically, the PZT 1170 includes a lower PZT width 1174 and an upper PZT width 1176. In the example shown, the upper PZT width 1176 may be greater than the lower PZT width 1174. As a result, shoulders on either side of the PZT 1170 are formed. These shoulders may be sloped regions extending from the top surfaces of the piezoelectric film 1130 to the lower surface of the PZT 1170. In some aspects, the shoulders of the PZT 1170 may be sloped according to the angle 1178. In some aspects, the sloped shoulders may be symmetrical about a central axis of the PZT 1170. In other aspects, the PZT 1170 may not be symmetrical. For example, one side of the PZT 1170 may be sloped more steeply than the other side or vice versa. Any suitable geometry of the PZT 1170 may be used.

As shown in FIG. 11, the PZT 1170 may be of a depth 1172 while the total thickness of the piezoelectric film 1130 may be a thickness 1160. In some aspects, performance of the SAW resonator 1100 may be dependent, at least in part, on the relationship between the depth 1172 of the PZT 1170 and the thickness 1160 of the piezoelectric film 1160. In some aspects, this relationship may be quantified as a percentage of the depth 1172 of the thickness 1160 or a ratio between the two.

As also shown in FIG. 11, the electrodes 1122 may be of a thickness 1150. The width of the electrodes 1122 may be a width 1132 and the electrodes 1122 may be spaced according to a pitch 1142. While not shown to avoid obscuring the drawings, additional layers be provided over all or a portion of the piezoelectric surface, within the PZT or and/or on top of the electrodes. This may include dielectric layers which may serve for temperature compensation, passivation, frequency trimming or other purposes.

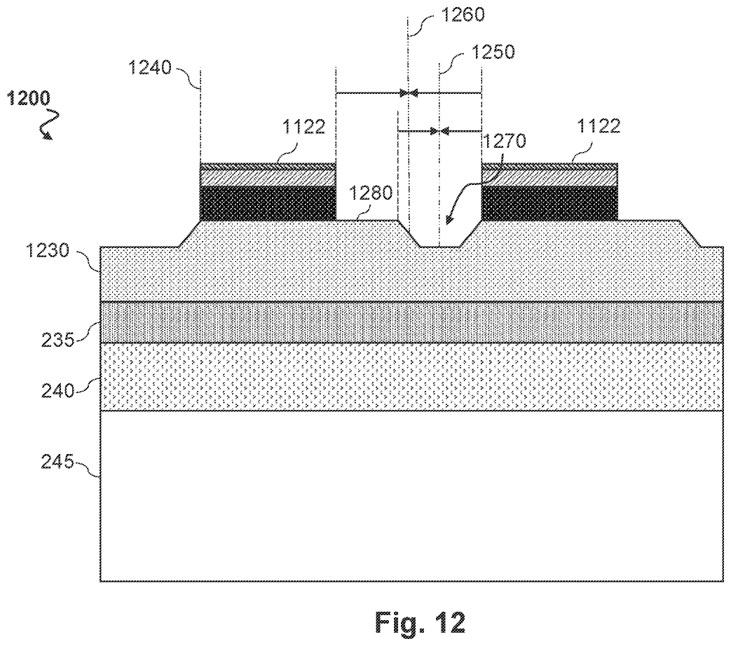

FIG. 12 is a cross-sectional side view of a SAW resonator 1200 with an offset piezoelectric trench 1270, according to aspects of the present disclosure. The SAW resonator 1200 may be similar to the SAW resonator 1100. In particular, the SAW resonator 1200 may include a piezoelectric film 1230. The piezoelectric film 1230 may be similar to the piezoelectric film 230 (FIG. 2) and/or the piezoelectric film 1130 (FIG. 11) previously described. In some aspects, the piezoelectric film 1230 may be positioned on the layers 235, 240, and 245 as shown in FIG. 12. The SAW resonator 1100 may also include multiple electrodes 1122. In some aspects, electrodes may overhang over the edge of plateaus.

The SAW resonator 1200 includes a PZT 1270. As shown in FIG. 12, the PZT 1270 may be offset between the electrodes 1122. In particular, a centerline 1260 is shown.

The centerline 1260 may illustrate the center point between the electrodes 1122. In addition, a centerline 1250 is shown. The centerline 1250 may illustrate the center point of the PZT 1270. As shown in FIG. 12, the centerline 1260 is not aligned with the centerline 1250. Specifically, the centerline 1250 may be positioned to the right of the centerline 1260.

However, in other aspects, the centerline 1250 of the PZT 1270 may be positioned left of the centerline 1260. Like the PZT 1170, the PZT 1270 may include tapered edges or shoulders, as shown. In some aspects, regions of the piezoelectric film 1230 between PZTs may be referred to as plateaus. In the example shown, a left edge of the electrodes 1122 may be aligned with a left edge of the piezoelectric plateaus on which they are positioned, as shown by the line 1240. As shown in FIG. 12, a ledge 1280 may be positioned to the right of the electrodes 1122. In some aspects in which piezoelectric plateaus are of a greater width than the electrodes 1122, the electrodes 1122 may be positioned at any suitable position along the plateau. For example, a ledge, such as the ledge 1280, may be positioned to the left of the electrodes 1122. In some aspects, a ledge may be positioned on either side of the electrodes 1122. In some aspects, the offset positioning of the electrodes 1122 relative to the PZTs 1270 of the SAW resonator 1200 may adjust the phase between transmitted and reflected acoustic waves along the IDT.

The SAW resonator 1200 may be manufactured according to any suitable method. For example, PZTs, such as the PZT 1270 may be formed within the piezoelectric film 1230 prior to positioning the electrodes 1122 on the piezoelectric film 1230. For example, the PZTs may be formed by lithography etching with a hard mask. This may include transferring a patterned design, including PZTs along the piezoelectric film 1230 between the planned positions of the electrodes 1122, onto a substrate. In some aspects, a hard mask may be a thin layer of material that is resistant to the etching process. After the PZTs are formed, the electrodes may be positioned along the piezoelectric film 1230 between the PZTs.

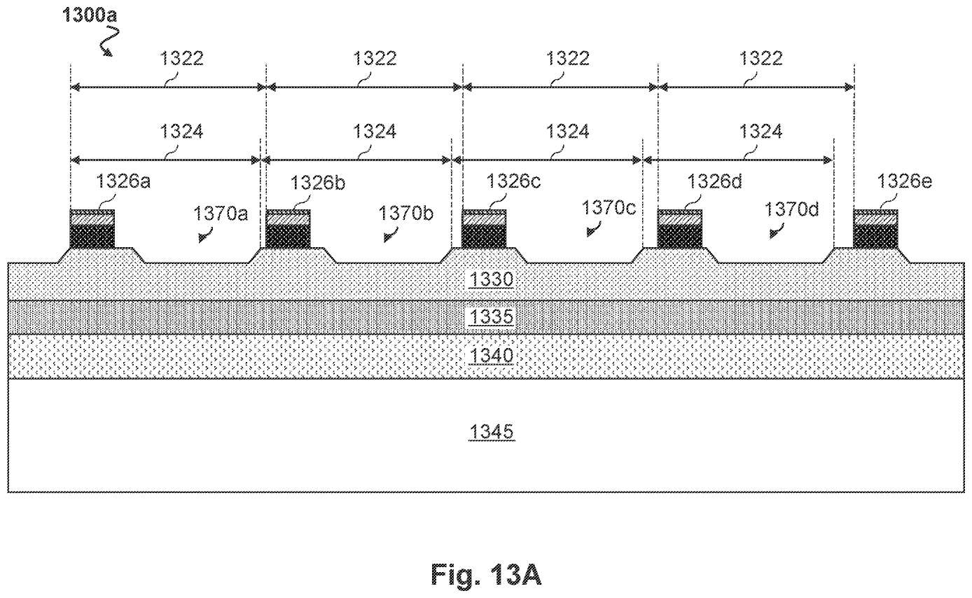

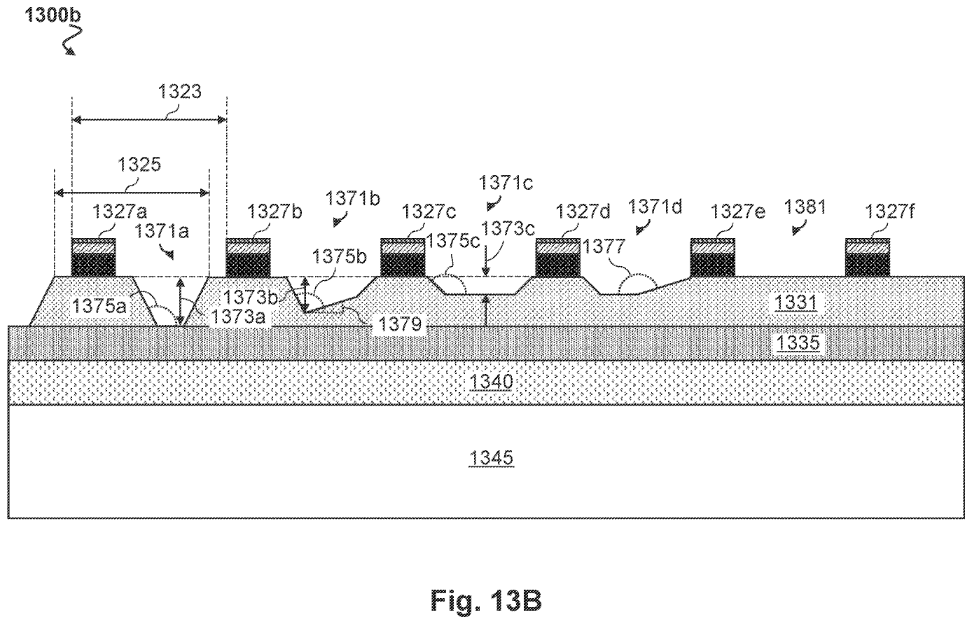

FIG. 13A is a cross-sectional side view of a SAW resonator 1300a with an electrode pitch different from a piezoelectric trench pitch, according to aspects of the present disclosure. As described previously, electrodes may be positioned on piezoelectric plateaus at any suitable position. In that regard, and as shown in FIG. 13A, the position of an electrode on a piezoelectric plateau may be varied on the same resonator.

The SAW resonator 1300a may include various components. The SAW resonator may be similar to the any of the SAW resonators described herein. In particular, the SAW resonator 1300a includes a carrier substrate 1345, a dielectric layer or trap rich layer 1340, a dielectric layer 1335, a piezoelectric film 1330, and five electrodes 1326.

The carrier substrate 1345 forms the foundation of the SAW resonator 1300a. The dielectric layer or trap rich layer 1340 is positioned on top of the carrier substrate 1345. The dielectric layer 1335 is positioned on top of the dielectric layer or trap rich layer 1340. The piezoelectric film 1330 is positioned on top of the dielectric layer 1335.

In the example shown in FIG. 13A, multiple PZTs are formed in the piezoelectric film 1330. The electrodes 1322 may be spaced from one another by an electrode pitch 1322. The PZTs 1370 may be spaced from one another by a PZT pitch 1324 different from the electrode pitch 1322. For example, the electrode 1326a may be positioned such that the left edge of the electrode 1326a is aligned with the left edge of the piezoelectric plateau to the left of the PZT 1370a. The electrode 1326b is spaced from the PZT 1370a by the electrode pitch 1322. The right edge of the PZT 1370a may be spaced from the neighboring PZT by the PZT pitch 1324. Because the electrode pitch 1322 is greater than the PZT 1324 in this example, the left most edge of the electrode 1326b may not be aligned with the right PZT 1370a, as shown. As each electrode 1326 and PZT 1370 shown is similarly spaced apart from each other by the electrode pitch 1322 and the PZT pitch 1324 respectively, each of electrodes 1326c, 1326d, and 1326e may be spaced to the right on their respective piezoelectric plateaus by increasing and constant degrees.

FIG. 13B is a cross-sectional side view of a SAW resonator 1300b with varying piezoelectric trench geometries, according to aspects of the present disclosure. As shown in FIG. 13B, the piezoelectric trenches of the SAW resonator 1300b may be of any suitable geometry.

In the example shown, the SAW resonator 1300b includes multiple electrodes 1326. The multiple electrodes 1327 may be spaced according to a pitch 1323 or the spacing between different pairs of electrodes can have different pitches or follow no periodicity with respect to other pairs of electrodes. However, it is noted that the electrodes 1327 may be spaced according to different pitches, as described with reference to FIG. 13A. The electrodes 1327 may also be spaced according to a piezoelectric trench pitch 1325 and may be spaced according to difference piezoelectric trench pitches, as described with reference to FIG. 13A.

In the example shown, a piezoelectric trench 1371a is shown between electrodes 1327a and 1327b. The piezoelectric trench 1371a may be of a depth 1373a. Similarly, the sides of the piezoelectric trench 1371a may be angled at an angle 1375a.

A piezoelectric trench 1371b is shown between electrodes 1327b and 1327c. The piezoelectric trench 1371b may be of a depth 1373b. Similarly, the sides of the piezoelectric trench 1371a may be angled at an any suitable angles. For example, a left side of the piezoelectric trench 1371b may be angled at the angle 1375b. In some aspects, the right side of the piezoelectric trench 1371b may be angled at a different angle. In addition, in some aspects, the bottom surface of the piezoelectric trench 1371b (or any other piezoelectric trench) may not be parallel with the SAW resonator 1300b. For example, the bottom surface of the piezoelectric trench 1371b may be angled at an angle 1379.

A piezoelectric trench 1371c is shown between electrodes 1327c and 1327d. The piezoelectric trench 1371c may be of a depth 1373c. The sides of the piezoelectric trench 1371c may be angled at an angle 1375c.

A piezoelectric trench 1371d is shown between electrodes 1327d and 1327e. The piezoelectric trench 1371d may be of a depth 1373d. Similarly, the sides of the piezoelectric trench 1371d may be angled at an angle. For example, a right side of the trench may be angled at an angle 1377 greater than an angle of the left side of the trench.

In some aspects, no piezoelectric trench may be formed between electrodes, such as the space 1381 between electrodes 1327e and 1327f. The benefit of such different geometries along the IDT of an surface acoustic wave device may include that a larger reflectivity of the reflector gratings is achieved, while the electrodes of the IDT use a different tradeoff between capacitance per area and reflectivity. In this manner SAW devices with variable PZT geometries will have an improved performance.

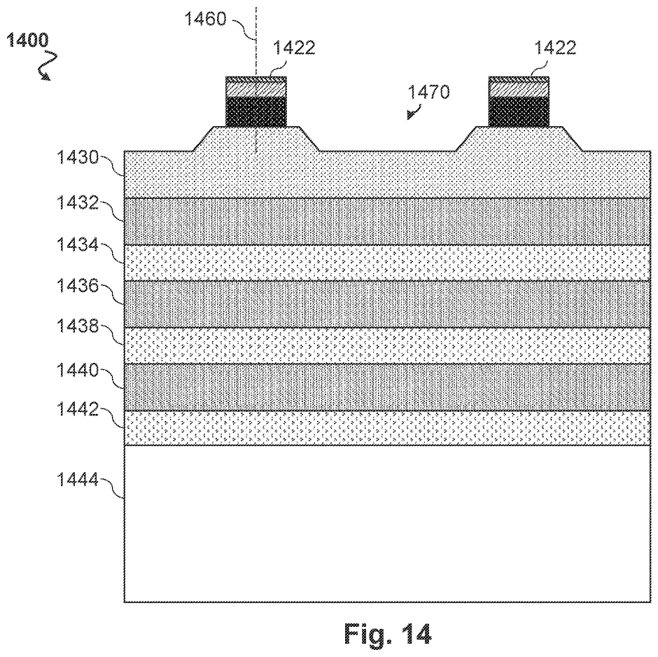

FIG. 14 is a cross-sectional side view of a AW resonator 1400 including a piezoelectric trench 1470 and a Bragg mirror, according to aspects of the present disclosure. As shown, the AW resonator 1400 may include multiple electrodes 1422 positioned on a piezoelectric film 1430. The piezoelectric film includes the PZT 1470. In the example shown in FIG. 14, the electrodes 1422 may be centrally aligned with the piezoelectric plateaus shown. For example, a central axis 1460 is shown corresponding both to the electrode 1422 as well as the piezoelectric plateau. In the example shown, because the width of the piezoelectric plateau is greater than the width of the electrode 1422, two ledges of equal size may be on either side of the electrode 1422. However, as with any of the electrodes and corresponding PZTs described herein, any suitable geometries may be used.

In the example shown in FIG. 14, the piezoelectric film 1430 may be positioned on a Bragg mirror. In the example shown, the Bragg mirror may include layers 1432, 1434, 1436, 1438, 1440, and 1442. These layers may be alternating layers of high and low acoustic impedance. Such layers may include dielectric or metallic materials. For example, the layer 1432 may be a high acoustic impedance dielectric layer. The layer 1434 may be a low acoustic impedance dielectric layer. The layer 1436 may be a high acoustic impedance dielectric layer. The layer 1438 may be a low acoustic impedance dielectric layer. The dielectric layer 1440 may be a high acoustic impedance dielectric layer. The dielectric layer 1442 may be a low acoustic impedance dielectric layer. In some examples, the layer 1444 may be a substrate similar to any of the substrates described herein.

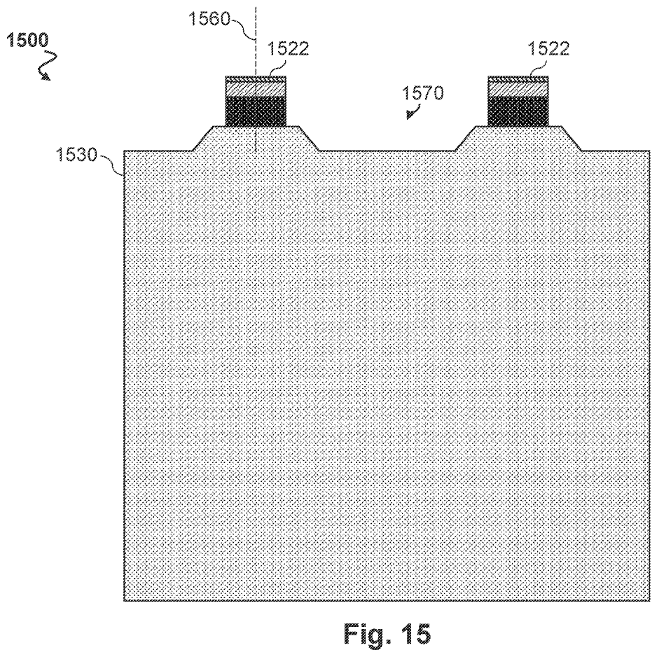

FIG. 15 is a cross-sectional side view of a SAW resonator 1500 including a piezoelectric trench 1570 formed in bulk piezoelectric material, according to aspects of the present disclosure. As shown, the SAW resonator 1500 may include multiple electrodes 1522 positioned on a bulk piezoelectric material 1530. The piezoelectric material includes the PZT 1570. In the example shown in FIG. 15, the electrodes 1522 may be centrally aligned with the piezoelectric plateaus shown. While not shown to avoid obscuring the drawings, additional layers may be provided over all or a portion of the piezoelectric surface, within the PZT or and/or on top of the electrodes. This may include dielectric layers which may serve for temperature compensation, passivation, frequency trimming or other purposes.

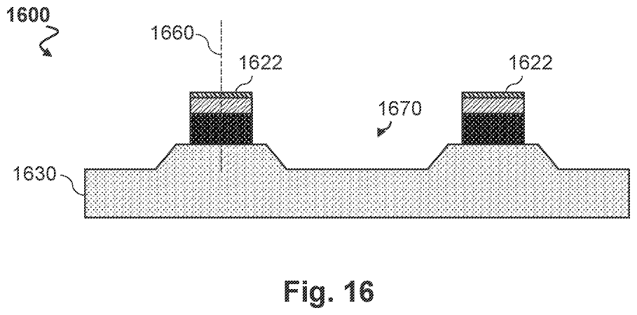

FIG. 16 is a cross-sectional side view of a AW resonator 1600 including a piezoelectric trench 1670 formed on a freestanding piezoelectric membrane 1630, according to aspects of the present disclosure. As shown, the AW resonator 1600 may include multiple electrodes 1622 positioned on a freestanding piezoelectric membrane 1630. The dielectric material includes the PZT 1670. In the example shown in FIG. 16, the electrodes 1622 may be centrally aligned with the piezoelectric plateaus shown. While not shown to avoid obscuring the drawings, additional layers may be provided over all or a portion of the piezoelectric surface, within the PZT and/or on top of the electrodes. This may include dielectric layers which may serve for temperature compensation, passivation, frequency trimming or other purposes. Furthermore, additional layers and geometries may be added to the bottom surface of the piezoelectric membranes. This may include dielectric layers or bottom electrodes and changes to the bottom topography of the piezoelectric membrane, including the formation of PZTs.

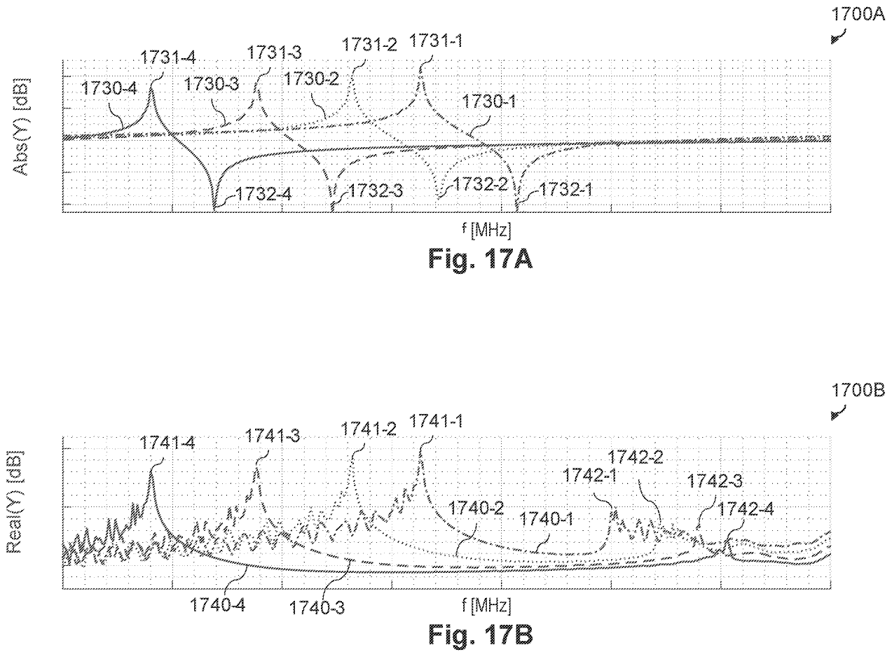

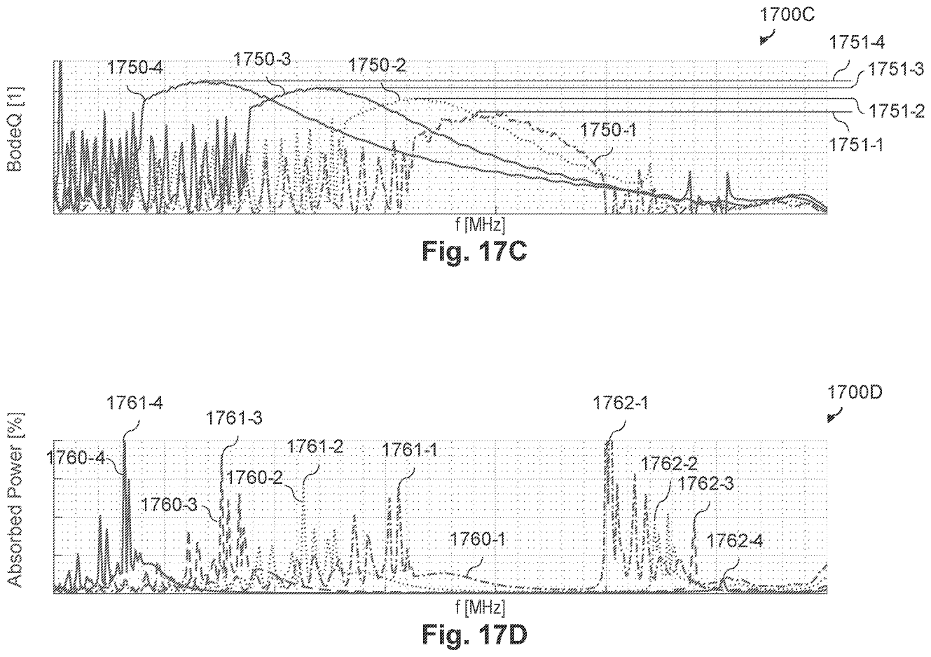

FIG. 17A is a graphical representation of the absolute value of the admittance of SAW resonators with piezoelectric trenches of varying relative depth, according to aspects of the present disclosure. FIG. 17A includes a plot 1700A. The plot 1700A includes a data set 1730-1, a data set 1730-2, a data set 1730-3, and a data set 1730-4. In some aspects, the data set 1730-1 may be a data set corresponding to a frequency response of a SAW resonator without a PZT. The data set 1730-2 may be a data set corresponding to a frequency response of a SAW resonator with a PZT of a first depth. In some aspects, the first depth may be within a range of between 9% and 15%. In one aspect, the first depth may be 12%. As previously described, a depth of a PZT may be defined in terms of a percentage of the PZT depth relative to the dielectric film thickness. For example, if the depth of the PZT is 70 nanometer and the thickness of the dielectric film is 700 nanometer, the depth of the PZT may be defined as 10%. Similarly, a ratio may be used. In the example of the PZT of 70 nanometer within a dielectric film of 700 nanometer, this depth may be defined as a 1:10 ratio. The data set 1730-3 may be a data set corresponding to a frequency response of a SAW resonator with a PZT of a second depth. In some aspects, the second depth may be within a range of between 15% and 21%. In one aspect, the second depth may be 18%. The data set 1730-4 may be a data set corresponding to a frequency response of a SAW resonator with a PZT of a third depth. In some aspects, the third depth may be within a range of between 21% and 27%. In one aspect, the first depth may be 24%. In that regard, a trench depth of 0% may correspond to an absence of a PZT. A trench depth of 100% may correspond to a fully-etched PZT. A fully-etched PZT may be a trench which extends completely through the film directly beneath the electrodes. For example, the PZT 1371a between electrodes 1327a and 1327b may be an example of a fully-etched PZT.

In some aspects, the data set 1730-1 includes a resonance frequency 1731-1 and an anti-resonance frequency 1732-1. As shown, the resonance frequency 1731-1 may be a lower frequency than the anti-resonance frequency 1732-1.

The data set 1730-2 includes a resonance frequency 1731-2 and an anti-resonance frequency 1732-2. The data set 1730-2 shows how the PZT trenches of the SAW resonator corresponding to the data set 1730-2 shifts the resonance frequency 1731-2 and the anti-resonance frequency 1732-2 downwards.

Similarly, the data set 1730-3 includes a resonance frequency 1731-3 and an anti-resonance frequency 1732-3. The data set 1730-3 shows how the PZT trenches of the SAW resonator corresponding to the data set 1730-3 shifts the resonance frequency 1731-3 and the anti-resonance frequency 1732-2 downwards.

The data set 1730-4 includes a resonance frequency 1731-4 and an anti-resonance frequency 1732-4. The data set 1730-4 shows how the PZT trenches of the SAW resonator corresponding to the data set 1730-4 shifts the resonance frequency 1731-4 and the anti-resonance frequency 1732-4 downwards.

FIG. 17B is a graphical representation of a frequency response of SAW resonators with piezoelectric trenches of varying relative depth, according to aspects of the present disclosure. FIG. 17B includes a plot 1700B. The plot 1700B includes a data set 1740-1, a data set 1740-2, a data set 1740-3, and a data set 1740-4. In some aspects, the data set 1740-1 may be a data set corresponding to a frequency response of a SAW resonator without a PZT, such as the same SAW resonator corresponding to the data set 1730-1 of FIG. 17A. The data set 1740-2 may be a data set corresponding to the SAW resonator of the data set 1730-2. The data set 1740-3 may be a data set corresponding to the SAW resonator of the data set 1730-3. The data set 1740-4 may be a data set corresponding to the SAW resonator of the data set 1730-4.

In some aspects, the data set 1740-1 includes a peak 1741-1 and a peak 1742-1. The data set 1740-2 includes a peak 1741-2 and a peak 1742-2. The data set 1740-3 includes a peak 1741-3 and a peak 1742-3. The data set 1740-4 includes a peak 1741-4 and a peak 1742-4.

As shown in FIG. 17B, as the depth of the PZT is increased, the peak corresponding to the upper stop band edge (e.g., peaks 1742-1, 1742-2, 1742-3, and 1742-4) may be moved higher along the frequency spectrum. As described in more detail hereafter, this shifting of the upper stop band edge may result in significantly improved performance of the SAW resonator and/or increased signal quality of a filter based on the SAW resonator.

FIG. 17C is a graphical representation of a quality factor of SAW resonators with piezoelectric trenches of varying relative depth, according to aspects of the present disclosure. FIG. 17C includes a plot 1700C. The plot 1700C includes a data set 1750-1, a data set 1750-2, a data set 1750-3, and a data set 1750-4. In some aspects, the data set 1750-1 may be a data set corresponding to a frequency response of a SAW resonator without a PZT, such as the same SAW resonator corresponding to the data set 1730-1 of FIG. 17A and/or the data set 1740-1 of FIG. 17B. The data set 1750-2 may be a data set corresponding to the SAW resonator of the data set 1730-2 and/or 1740-2. The data set 1750-3 may be a data set corresponding to the SAW resonator of the data set 1730-3 and/or 1740-3. The data set 1750-4 may be a data set corresponding to the SAW resonator of the data set 1730-4 and/or 1740-4.

As shown in FIG. 17C, the quality factor of the SAW resonators increases with depth of PZT trench. For example, a peak of the quality factor shown in data set 1750-1 is shown by the line 1751-1. A peak of the quality factor shown in data set 1750-2 is shown by the line 1751-2. As shown, the peak shown by the line 1751-2 is greater than the peak shown by the line 1751-1. A peak of the quality factor shown in data set 1750-3 is shown by the line 1751-3 and the peak shown by the line 1751-3 is greater than the peak shown by the line 1751-2. Finally, a peak of the quality factor shown in data set 1750-4 is shown by the line 1751-4 and the peak shown by the line 1751-4 is greater than the peak shown by the line 1751-3.

In some aspects, an increase in the quality factor of a SAW resonator may correspond to a reduced loss of the SAW resonator. In some aspects, this reduced loss may be a result of acoustic energy being located further away from the metal electrodes. In that regard, the more the trench depth is increased, the more the quality factor is improved up to a limit. By protecting the top side of the electrodes, e.g., using a sacrificial layer which can be removed in later fabrication steps, the depth of the piezoelectric trenches may be increased without affecting the thickness of the electrodes allowing for any suitable trench depth.

FIG. 17D is a graphical representation of dissipated power of SAW resonators with piezoelectric trenches of varying relative depth, according to aspects of the present disclosure. The dissipated power may also be referred to as absorbed power. FIG. 17D includes a plot 1700D. The plot 1700D includes a data set 1760-1, a data set 1760-2, a data set 1760-3, and a data set 1760-4. In some aspects, the data set 1760-1 may be a data set corresponding to a frequency response of a SAW resonator without a PZT, such as the same SAW resonator corresponding to the data sets 1730-1, 1740-1, and/or 1750-1. The data set 1760-2 may be a data set corresponding to the SAW resonator of the data sets 1730-2, 1740-2, and/or 1750-2. The data set 1760-3 may be a data set corresponding to the SAW resonator of the data sets 1730-3, 1740-3, and/or 1750-3. The data set 1760-4 may be a data set corresponding to the SAW resonator of the data sets 1730-4, 1740-4, and/or 1750-5.

In some aspects, the data set 1760-1 includes a peak 1761-1 and a peak 1762-1. The data set 1760-2 includes a peak 1761-2 and a peak 1762-2. The data set 1760-3 includes a peak 1761-3 and a peak 1762-3. The data set 1760-4 includes a peak 1761-4 and a peak 1762-4.

As shown in FIG. 17D, as the depth of the PZT is increased, the peak corresponding to the upper stop band edge (e.g., peaks 1762-2, 1762-3, and 1762-4) may be moved higher along the frequency spectrum.

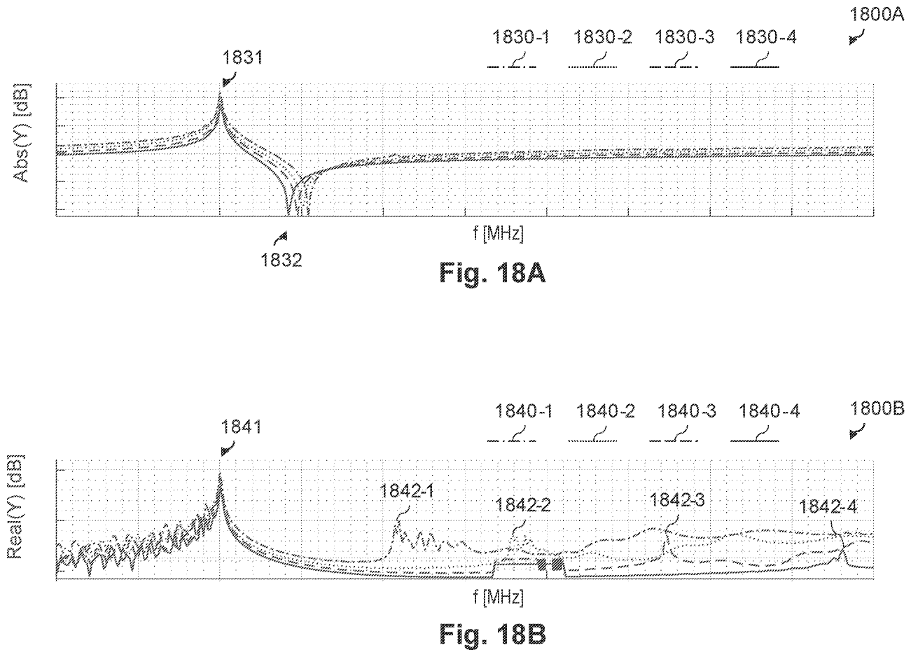

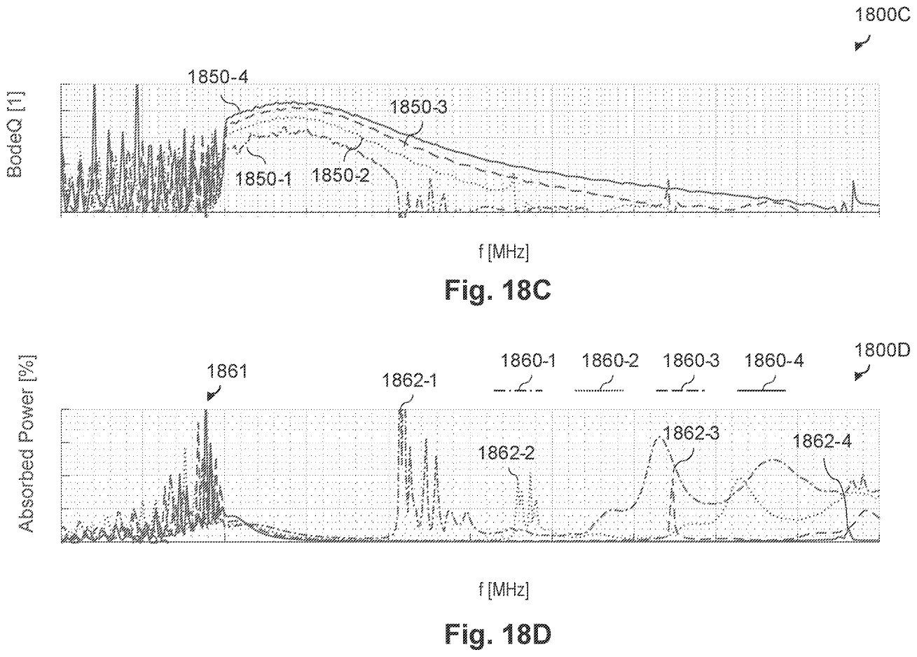

FIG. 18A is a graphical representation of the absolute value of the admittance of SAW resonators with piezoelectric trenches of varying depths normalized to the resonance frequency, according to aspects of the present disclosure. As described previously, the inclusion of a PZT within a SAW resonator may result in a decrease in the fundamental resonance frequency. To compensate for the shift in fundamental resonance frequency, the SAW resonator may be selected such that, after a trim without PAS procedure, the final resonance frequency corresponds to the desired target resonance frequency. Or, in other aspects, the SAW resonator may be designed to include PZTs as explained and designed to the desired resonance frequency. To illustrate the effect of the PZTs positioned within SAW resonators of the same fundamental frequency, the data of FIGS. 18A-18D may be normalized about the fundamental resonance frequency. For example, the data of FIGS. 18A-18D may correspond to the data of FIGS. 17A-17D, but may be divided by the resonance frequency of each data set.

In that regard, FIG. 18A includes a plot 1800A. The plot 1800A includes a data set 1830-1, a data set 1830-2, a data set 1830-3, and a data set 1830-4. In some aspects, the data set 1830-1 may be a data set corresponding to a frequency response of a SAW resonator without a PZT. The data set 1830-2 may be a data set corresponding to a frequency response of a SAW resonator with a PZT of a first depth. In some aspects, the first depth of the PZT of FIGS. 18A-18D may be the same as the first depth of the PZT of FIGS. 17A-17D, or may differ. The data set 1830-3 may be a data set corresponding to a frequency response of a SAW resonator with a PZT of a second depth, which may be the same or different than the second depth of the PZT of FIGS. 17A-17D. The data set 1830-4 may be a data set corresponding to a frequency response of a SAW resonator with a PZT of a third depth, which may be the same or different than the third depth of the PZT of FIGS. 17A-17D.

As shown in FIG. 18A, each of the datasets 1830-1, 1830-2, 1830-3, and 1830-4 include a peak 1831 aligned about the normalized fundamental frequency. Each of the datasets 1830-1, 1830-2, 1830-3, and 1830-4 also include an anti-resonance frequency 1832. As shown, the anti-resonance frequencies 1832 may not be aligned with one another, but may be similar. This may result in a slight decrease in effective coupling coefficient of the SAW resonator.

FIG. 18A also shows how the overall amplitude of the datasets 1830-1, 1830-2, 1830-3, and 1830-4 decreases as the PZT depth increases. This may indicate a decrease in capacitance of the SAW resonator.

FIG. 18B is a graphical representation of a frequency response of SAW resonators with piezoelectric trenches of varying depths normalized to the resonance frequency, according to aspects of the present disclosure. FIG. 18B includes a plot 1800B. The plot 1800B includes a data set 1840-1, a data set 1840-2, a data set 1840-3, and a data set 1840-4. In some aspects, the data set 1840-1 may be a data set corresponding to a frequency response of a SAW resonator without a PZT, such as the same SAW resonator corresponding to the data set 1830-1 of FIG. 18A. The data set 1840-2 may be a data set corresponding to the SAW resonator of the data set 1830-2. The data set 1840-3 may be a data set corresponding to the SAW resonator of the data set 1830-3. The data set 1840-4 may be a data set corresponding to the SAW resonator of the data set 1830-4.

Like the plot 1800A, the data sets of the plot 1800B are normalized about the resonance frequency for comparison. As a result, the peak 1841 of each of the datasets 1840-1, 1840-2, 1840-3, and 1840-4 is aligned about the central normalized frequency.

In some aspects, the data set 1840-1 includes a peak 1842-1. The peak 1842-1 may correspond to an upper stop band edge of the resonator. The data set 1840-2 includes a peak 1842-2. The data set 1840-3 includes a peak 1842-3. The data set 1840-4 includes a peak 1842-4.

As described with reference to FIG. 17B previously, as the depth of the PZT is increased, the peak corresponding to the upper stop band edge may be moved higher along the frequency spectrum. The degree to which this shift in the upper stop band edge occurs is shown more clearly by the plot 1800B of FIG. 18B as the fundamental frequency has been normalized. As shown, the peak 1842-2 corresponding to a first PZT depth is significantly higher in frequency than the peak 1842-1. In addition, the peak 1842-3 is higher in frequency than the peak 1842-2 and the peak 1842-4 corresponding to the greatest depth of the example provided is higher in frequency still. This shifting of the upper stop band edge may move spurious content out of the passband of the frequency as well as out of passbands of other filters leading to significantly increased signal quality and performance of multiplexer circuits.

It is also noted that each of peaks 1842-2, 1842-3, and 1842-4, in addition to being shifted higher in frequency, are of successively lower amplitude. As a result, the degree of spurious content which may interfere with other bands of other filters is also significantly reduced leading to greatly improved signal quality.

FIG. 18C is a graphical representation of a quality factor of SAW resonators with piezoelectric trenches of varying depths normalized to a central fundamental frequency, according to aspects of the present disclosure. FIG. 18C includes a plot 1800C. The plot 1800C includes a data set 1850-1, a data set 1850-2, a data set 1850-3, and a data set 1850-4. In some aspects, the data set 1850-1 may be a data set corresponding to a frequency response of a SAW resonator without a PZT, such as the same SAW resonator corresponding to the data set 1830-1 of FIG. 18A and/or the data set 1840-1 of FIG. 18B. The data set 1850-2 may be a data set corresponding to the SAW resonator of the data set 1830-2 and/or 1840-2. The data set 1850-3 may be a data set corresponding to the SAW resonator of the data set 1830-3 and/or 1840-3. The data set 1850-4 may be a data set corresponding to the SAW resonator of the data set 1830-4 and/or 1840-4. As shown in FIG. 18C, the quality factor of the SAW resonators increases with depth of PZT. As shown, the quality factor of SAW resonators may improve with depth of PZT at the fundamental resonance frequency (Qs), the anti-resonance frequency (Qp) as well as the overall peak quality factor frequency (Qmax) and frequencies above the anti-resonance frequency up to the upper stop band edge and beyond.

FIG. 18D is a graphical representation of dissipated power of SAW resonators with piezoelectric trenches of varying depths normalized to a central fundamental frequency, according to aspects of the present disclosure. FIG. 18D includes a plot 1800D. The plot 1800D includes a data set 1860-1, a data set 1860-2, a data set 1860-3, and a data set 1860-4. In some aspects, the data set 1860-1 may be a data set corresponding to a frequency response of a SAW resonator without a PZT, such as the same SAW resonator corresponding to the data sets 1830-1, 1840-1, and/or 1850-1. The data set 1860-2 may be a data set corresponding to the SAW resonator of the data sets 1830-2, 1840-2, and/or 1850-2. The data set 1860-3 may be a data set corresponding to the SAW resonator of the data sets 1830-3, 1840-3, and/or 1850-3. The data set 1860-4 may be a data set corresponding to the SAW resonator of the data sets 1830-4, 1840-4, and/or 1850-4.

In some aspects, the data sets 1860-1, 1860-2, 1860-3, and 1860-4 may each include a peak 1861. The data set 1860-1 may include a peak 1862-1. The data set 1860-2 may include a peak 1862-2. The data set 1860-3 may include a peak 1862-3. The data set 1860-4 may include a peak 1862-4.

As shown in FIG. 18D, as the depth of the PZT is increased, the peak corresponding to the upper stop band edge (e.g., peaks 1862-2, 1862-3, and 1862-4) may be moved higher along the frequency spectrum.

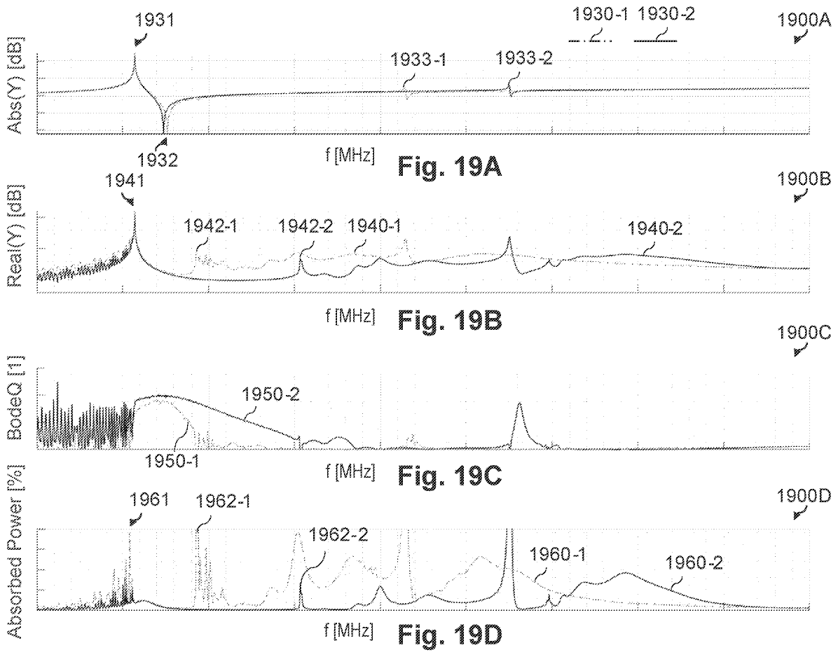

FIG. 19A is a graphical representation of a comparison of the absolute value of the admittance of SAW resonators with and without piezoelectric trenches, according to aspects of the present disclosure. FIG. 19A includes a plot 1900A. The plot 1900A includes a data set 1930-1 and a data set 1930-2. The data set 1930-1 may correspond to SAW resonator without any PZTs. The data set 1930-2 may correspond to a SAW resonator with PZTs. The data set 1930-2 may correspond to a SAW resonator with PZTs of depth between 6% and 24%. In some aspects, unlike the plots of FIGS. 18A-18D described previously, the datasets of FIGS. 19A-19D may be data corresponding to frequency responses of SAW resonators in terms of absolute frequency. That is, the dataset 1930-2 may be a SAW resonator with PZTs designed with a fundamental resonance frequency to match the fundamental resonance frequency of the SAW resonator without PZTs of the dataset 1930-1 for comparison of performance. A reduction in velocity implies that a smaller electrode pitch may be used for a resonator with larger PZT depth to achieve the same resonance frequency. As shown, each of the datasets 1930-1 and 1930-2 includes a peak 1931 corresponding to the fundamental resonance frequency. Each of the datasets 1930-1 and 1930-2 may also include a peak 1932 corresponding to an anti-resonance frequency.

As shown in FIG. 19A, the dataset 1930-1 may also include a higher order resonance mode 1933-1. The dataset 1930-2 may include a higher order resonance mode 1933-2. As shown, due to the presence of the PZTs, the higher order resonance mode 1933-2 is shifted higher in frequency than the higher order resonance mode 1933-1.

FIG. 19B is a graphical representation of a comparison of the conductance of SAW resonators with and without piezoelectric trenches, according to aspects of the present disclosure. FIG. 19B includes a plot 1900B. The plot 1900B includes a data set 1940-1 and a data set 1940-2. The data set 1940-1 may correspond to SAW resonator without any PZTs, such as the SAW resonator corresponding to the dataset 1930-1. The data set 1930-2 may correspond to a SAW resonator with PZTs, such as the SAW resonator corresponding to the dataset 1930-2. As shown, each of the datasets 1940-1 and 1940-2 includes a peak 1941 corresponding to the fundamental resonance frequency.

As shown in FIG. 19B, the dataset 1940-1 may also include a peak 1942-1 corresponding to the upper stop band edge of the resonator. The dataset 1940-2 may also include a peak 1942-2 corresponding to the upper stop band edge of the resonator.

In some aspects, FIG. 19B illustrates how the inclusion of PZTs may help to improve the signal quality of content within the passband, as well as significantly shift and/or decrease out of band content. For example, the upper stop band edge of the peak 1942-2 may be extended upward along the frequency spectrum significantly. The amplitude of the upper stop band edge of the peak 1942-2 is also significantly decreased. As a result, the SAW resonator of 1940-2 may exhibit much less interference with other bands of other filters in a multiplexer. This significantly improves the performance of a multiplexer.

FIG. 19C is a graphical representation of a comparison of quality factor of SAW resonators with and without piezoelectric trenches, according to aspects of the present disclosure. FIG. 19C includes a plot 1900C. The plot 1900C includes a data set 1950-1 and a data set 1950-2. In some aspects, the data set 1950-1 may be a data set corresponding to a frequency response of a SAW resonator without a PZT, such as the same SAW resonator corresponding to the data set 1930-1 of FIG. 19A and/or the data set 1940-1 of FIG. 19B. The data set 1950-2 may be a data set corresponding to the SAW resonator of the data set 1930-2 and/or 1940-2. As shown in FIG. 19C, the quality factor of the SAW resonators increases with depth of PZT trench.

FIG. 19D is a graphical representation of a comparison of dissipated power of SAW resonators with and without piezoelectric trenches, according to aspects of the present disclosure. FIG. 19D includes a plot 1900D. The plot 1900D includes a data set 1960-1 and a data set 1960-2. In some aspects, the data set 1960-1 may be a data set corresponding to a frequency response of a SAW resonator without a PZT, such as the same SAW resonator corresponding to the data sets 1930-1, 1940-1, and/or 1950-1. The data set 1960-2 may be a data set corresponding to the SAW resonator of the data sets 1930-2, 1940-2, and/or 1950-2.

In some aspects, the data sets 1960-1 and 1960-2 may each include a peak 1961. The data set 1960-1 may include a peak 1962-1. The data set 1960-2 may include a peak 1962-2. As shown in FIG. 19D, as the depth of the PZT is increased, the peak corresponding to the upper stop band edge (e.g., peak 1962-2) may be moved higher along the frequency spectrum.

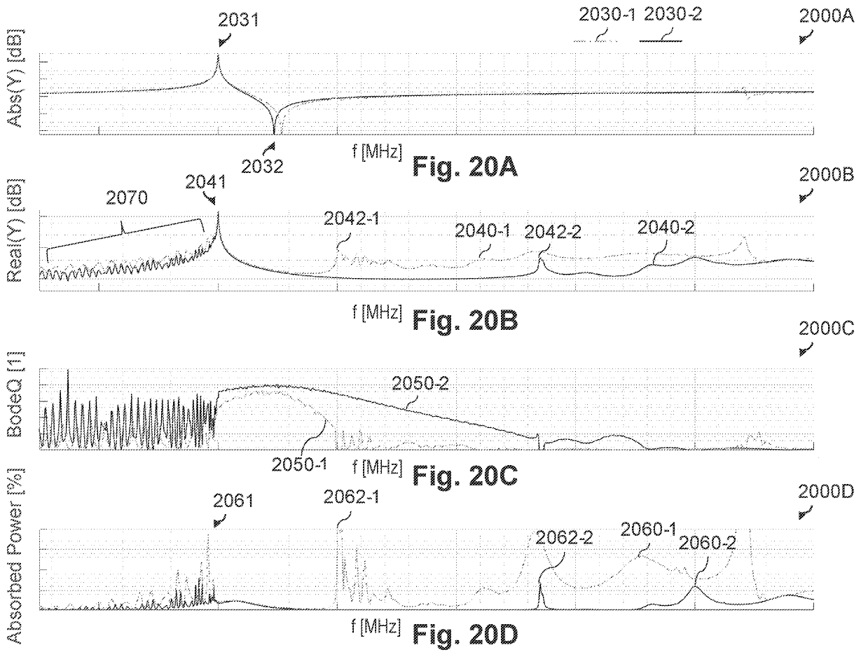

FIG. 20A is a graphical representation of the absolute value of the admittance of SAW resonators with piezoelectric trenches of varying depths normalized to a central fundamental frequency, according to aspects of the present disclosure. FIG. 20A includes a plot 2000A. The plot 2000A includes a data set 2030-1 and a data set 2030-2. In some aspects, the data set 2030-1 may be a data set corresponding to a frequency response of a SAW resonator without a PZT. The data set 2030-2 may be a data set corresponding to a frequency response of a SAW resonator with a PZT.

As shown in FIG. 20A, each of the datasets 2030-1 and 2030-2 include a peak 2031 aligned about the normalized fundamental frequency. Each of the datasets 2030-1 and 2030-2 also include an anti-resonance frequency 2032. As shown, the anti-resonance frequencies 2032 may not be aligned with one another but may be similar. This may result in a slight decrease in coupling coefficient of the SAW resonator.

FIG. 20B is a graphical representation of a frequency response of SAW resonators with piezoelectric trenches of varying depths normalized to a central fundamental frequency, according to aspects of the present disclosure. FIG. 20B includes a plot 2000B. The plot 2000B includes a data set 2040-1 and a data set 2040-2. In some aspects, the data set 2040-1 may be a data set corresponding to a frequency response of a SAW resonator without a PZT, such as the same SAW resonator corresponding to the data set 2030-1 of FIG. 20A. The data set 2040-2 may be a data set corresponding to the SAW resonator of the data set 2030-2.

Like the plot 2000A, the data sets of the plot 2000B are normalized about the fundamental frequency for comparison. As a result, the peak 2041 of each of the datasets 2040-1 and 2040-2 is aligned about the central normalized frequency.

In some aspects, the data set 2040-1 includes a peak 2042-1. The peak 2042-1 may correspond to an upper stop band edge of the filter. The data set 2040-2 includes a peak 2042-2. As the depth of the PZT is increased, the peak corresponding to the upper stop band edge may be moved higher along the frequency spectrum. As shown in FIG. 20B, the peak 2042-2 corresponding is significantly higher in frequency than the peak 2042-1. This shifting of the upper stop band edge may move spurious content out of the passband of a filter as well as out of passbands of other filters leading to significantly increased signal quality and performance of multiplexer circuits.

It is also noted that the peak 2042-2, in addition to being shifted higher in frequency, is of lower amplitude. As a result, the degree of spurious content which may interfere with other bands of other filters is also significantly reduced leading to greatly improved signal quality.

FIG. 20C is a graphical representation of a quality factor of SAW resonators with piezoelectric trenches of varying depths normalized to a central fundamental frequency, according to aspects of the present disclosure. FIG. 20C includes a plot 2000C. The plot 2000C includes a data set 2050-1 and a data set 2050-2. In some aspects, the data set 2050-1 may be a data set corresponding to a frequency response of a SAW resonator without a PZT, such as the same SAW resonator corresponding to the data set 2030-1 of FIG. 20A and/or the data set 2040-1 of FIG. 20B. The data set 2050-2 may be a data set corresponding to the SAW resonator of the data set 2030-2 and/or 2040-2. As shown in FIG. 20C, the quality factor of the SAW resonators increases with depth of PZT trench.

FIG. 20D is a graphical representation of dissipated power of SAW resonators with piezoelectric trenches of varying depths normalized to a central fundamental frequency, according to aspects of the present disclosure. FIG. 20D includes a plot 2000D. The plot 2000D includes a data set 2060-1 and a data set 2060-2. In some aspects, the data set 2060-1 may be a data set corresponding to a frequency response of a SAW resonator without a PZT, such as the same SAW resonator corresponding to the data sets 2030-1, 2040-1, and/or 2050-1. The data set 2060-2 may be a data set corresponding to the SAW resonator of the data sets 2030-2, 2040-2, and/or 2050-2. In some aspects, the data sets 2060-1 and 2060-2 may each include a peak 2061. The data set 2060-1 may include a peak 2062-1. The data set 2060-2 may include a peak 2062-2. As shown in FIG. 20D, the peak 2062-2 is both shifted significantly higher than the peak 2062-1 as well as drastically reduced, resulting in significantly improved performance of the SAW resonator with PZTs.

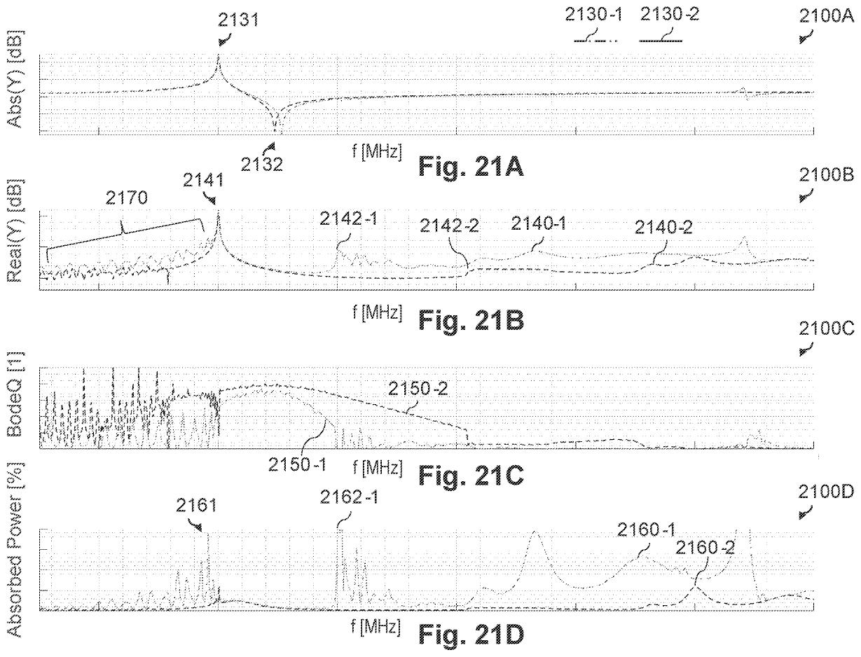

FIG. 21A is a graphical representation of a comparison of the absolute value of the admittance of SAW resonators without piezoelectric trenches and without modulated pitch and with piezoelectric trenches and with modulate pitch, according to aspects of the present disclosure. In some aspects, the data shown in FIGS. 21A-21D may illustrates the benefits of combining the addition of PZTs to a SAW resonator in conjunction with pitch modulation of the electrodes. Such pitch modulation may include varying the pitch between electrodes within the same SAW resonator. This may include lowering or increasing the pitch of reflector gratings as well as lowering or increasing the pitch of individual electrode pairs or groups of electrodes.

In some aspects, pitch modulation may be applied to series resonators but not parallel resonators. In some aspects, pitch modulation may be applied to parallel resonators but not series resonators. In some aspects, SAW resonators with both PZTs and pitch modulation may be used as both parallel resonators and series resonators.

As shown in FIG. 20B, described previously, a SAW resonator may include spurious content 2070 below the fundamental resonance frequency 2041. This spurious content 2070 may sometimes be referred to as beating. This beating, which is close to the passband of the filter in question, may negatively impact the signal quality within the passband. One solution to reducing the amplitude of the spurious content 2070 to improve the signal quality within the passband is to apply pitch modulation to the SAW resonator. In such case, the spurious content 2070 may be significantly improved, as shown by the region 2170 of the dataset 2140-2 of FIG. 21B. However, a drawback of pitch modulation is that it decreases the frequency of the upper stop band edge of a SAW resonator, which may interfere with the passband of the filter and/or the passbands of other filters of a multiplexer circuit. The introduction of PZTs to the SAW resonator solves this problem, as will be described in more detail with reference to FIGS. 21A-21D below.

As shown, FIG. 21A includes a plot 2100A. The plot 2100A includes a data set 2130-1 and a data set 2130-2. In some aspects, the data set 2130-1 may be a data set corresponding to a frequency response of a SAW resonator without a PZT. The data set 2130-2 may be a data set corresponding to a frequency response of a SAW resonator with a PZT and pitch modulation.

As shown in FIG. 21A, each of the datasets 2130-1 and 2130-2 include a peak 2131 aligned about the normalized fundamental frequency. Each of the datasets 2130-1 and 2130-2 also include an anti-resonance frequency 2132. As shown, the anti-resonance frequencies 2132 may not be aligned with one another but may be similar. This may result in a slight decrease in coupling coefficient of the SAW resonator.

FIG. 21B is a graphical representation of a comparison of the conductance of SAW resonators without piezoelectric trenches and without modulated pitch and with piezoelectric trenches and with modulated pitch, according to aspects of the present disclosure. FIG. 21B includes a plot 2100B. The plot 2100B includes a data set 2140-1 and a data set 2140-2. In some aspects, the data set 2140-1 may be a data set corresponding to a frequency response of a SAW resonator without a PZT, such as the same SAW resonator corresponding to the data set 2130-1 of FIG. 21A. The data set 2140-2 may be a data set corresponding to the SAW resonator of the data set 2130-2.

Like the plot 2100A, the data sets of the plot 2100B are normalized about the fundamental frequency for comparison. As a result, the peak 2141 of each of the datasets 2140-1 and 2140-2 is aligned about the central normalized frequency.

In some aspects, the data set 2140-1 includes a peak 2142-1. The peak 2142-1 may correspond to an upper stop band edge of the filter. The data set 2140-2 includes a peak 2142-2 corresponding to the upper stop band edge of a resonator including PZTs and pitch modulation. As shown in FIG. 21B, the region 2170 is significantly smoothed compared to the beating 2070 shown in FIG. 20B. This may be a result of the pitch modulation introduced to the SAW resonator of FIG. 21B. As previously described, a drawback of pitch modulation is a subsequent decrease in the upper stop band edge which may interfere with the passband. However, by including PZTs within the SAW resonator in addition to the pitch modulation, this decrease in frequency of the upper stop band edge has little to no impact on the passband because the upper stop band edge, shown by the peak 2142-2 in FIG. 21B, is already removed so far from the passband and drastically decreased. As a result, a SAW resonator that includes both pitch modulation and PZTs may include both a significantly smoothed response below the fundamental frequency 2141 as well as a significantly smoothed response well above the antiresonance frequency.

FIG. 21C is a graphical representation of a comparison of quality factor of SAW resonators without piezoelectric trenches and without modulated pitch and with piezoelectric trenches and with modulate pitch, according to aspects of the present disclosure. FIG. 21C includes a plot 2100C. The plot 2100C includes a data set 2150-1 and a data set 2150-2. In some aspects, the data set 2150-1 may be a data set corresponding to a frequency response of a SAW resonator without a PZT, such as the same SAW resonator corresponding to the data set 2130-1 of FIG. 21A and/or the data set 2140-1 of FIG. 21B. The data set 2150-2 may be a data set corresponding to the SAW resonator of the data set 2130-2 and/or 2140-2. As shown in FIG. 21C, the quality factor of the SAW resonators increases with depth of PZT trench and the frequency region of high quality factor and hence low losses increases significantly. In addition, significant smoothing of beating is also observed below the fundamental resonance frequency of 1 in comparison of FIG. 21C and FIG. 20C.

FIG. 21D is a graphical representation of a comparison of dissipated power of SAW resonators without piezoelectric trenches and without modulated pitch and with piezoelectric trenches and with modulate pitch, according to aspects of the present disclosure. FIG. 21D includes a plot 2100D. The plot 2100D includes a data set 2160-1 and a data set 2160-2. In some aspects, the data set 2160-1 may be a data set corresponding to a frequency response of a SAW resonator without a PZT, such as the same SAW resonator corresponding to the data sets 2130-1, 2140-1, and/or 2150-1. The data set 2160-2 may be a data set corresponding to the SAW resonator of the data sets 2130-2, 2140-2, and/or 2150-2. In some aspects, the data sets 2160-1 and 2160-2 may each include a peak 2161. The data set 2160-1 may include a peak 2162-1. The data set 2160-2 shows that the higher order peak of the data set 2160-2 is so drastically reduced by the PZTs and/or pitch modulation, that it is almost imperceptible. FIG. 21D also shows significantly reduced spurious content below the fundamental resonance frequency.

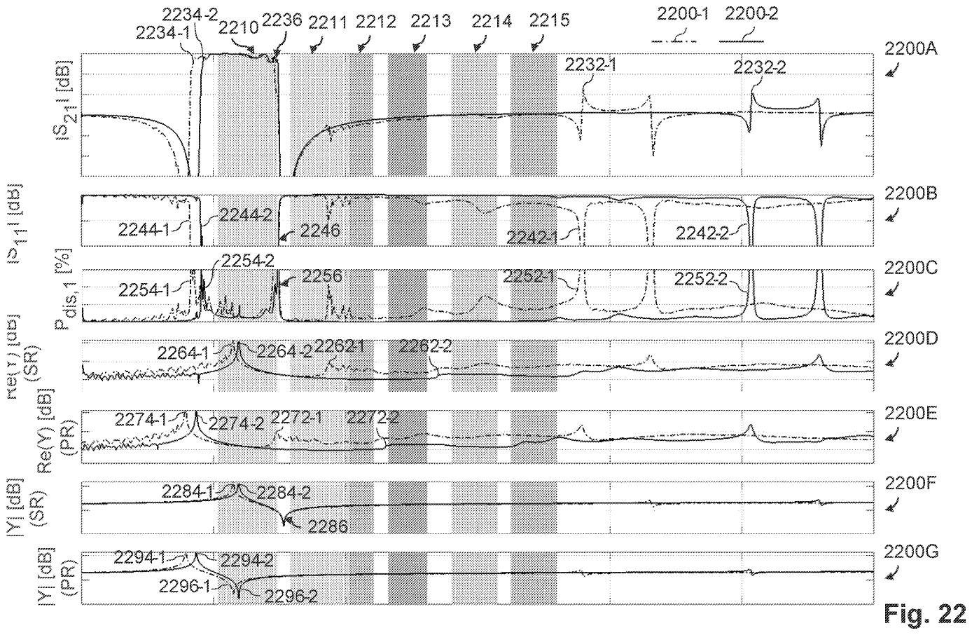

FIG. 22 is a graphical representation of a comparison of performance of acoustic wave devices with and without piezoelectric trenches, according to aspects of the present disclosure. FIG. 22 includes a plot 2200A. In some aspects, the plot 2200A corresponds to a comparison of a frequency response of a filter, including SAW resonators which do not include PZTs with a frequency response of a filter including SAW resonators which include PZTs and use modulation of the electrode pitches for improved performance. The plots include data 2200-1 corresponding to aspects of a filter with SAW resonators without PZTs as well as data 2200-2 corresponding to aspects of a filter with SAW resonators with PZTs.

Each of the plots of FIG. 22 also highlight multiple frequency bands for mobile communication. For example, a frequency band 2210 is shown corresponding to the passband of the filter. However, other frequency bands highlighted may correspond to other frequency regions corresponding to filter passbands within a multiplexer circuit or any other suitable circuit. These other bands include band 2211, band 2212, band 2213, band 2214, and band 2215.

As shown in plot 2200A, the frequency response corresponding to the filter without PZTs includes a lower band edge 2234-1 and an upper band edge 2236. The frequency response corresponding to the filter with PZTs includes a lower band edge 2234-2 and an upper band edge 2236. As shown, one effect of applying PZTs to one or more SAW resonators of a filter may include narrowing the passband of the filter.

As also shown in the plot 2200A, the frequency response corresponding to the filter without PZTs includes a higher order mode 2232-1. The frequency response corresponding to the filter with PZTs includes a higher order mode 2232-2. The higher order mode 2232-2 is positioned at a significantly higher frequency than the higher order mode 2232-1. In addition, the upper out-of-band content is generally much smoother in the frequency response of the filter with PZTs (2200-2).

The plot 2200B also illustrates the reflection coefficient at port 1 of the filter without PZTs compared to the reflection coefficient at port 1 of the filter with PZTs. A lower band edge 2244-1 may, for example, be aligned in frequency with the lower band edge 2234-1. Similarly, the lower band edge 2244-2 may be aligned in frequency with the lower band edge 2234-2. The upper band edge 2246 may be aligned with the upper band edge 2236. In addition, the dip in reflection coefficient 2242-1 is shown aligned with the higher order mode 2232-1. Similarly, the dip in reflection coefficient 2242-2 is shown aligned with the higher order mode 2232-2.

The plot 2200C also illustrates the dissipated power of a filter without PZTs compared to a frequency response corresponding to the filter with PZTs. A peak in dissipated power 2254-1 may, for example, be aligned in frequency with the lower band edge 2234-1. Similarly, the peak in dissipated power 2254-2 may be aligned in frequency with the lower band edge 2234-2. The peak in dissipated power 2256 may be aligned with the upper band edge 2236. In addition, peak 2252-1 is shown aligned with the higher order mode 2232-1. Similarly, the peak 2252-2 is shown aligned with the higher order mode 2232-2. As shown in the plots 2200B and 2200C, out-of-band losses are significantly reduced for the filter with SAW resonators with PZTs (2200-2).

Plot 2200D shows a conductance of a series resonator within a ladder filter. As shown in FIG. 22, the peak 2264-1 may be aligned with the center of the passband of the filter 2200-1 without PZTs. The peak 2264-2 may be aligned with the center of the passband of the filter 2200-2 with PZTs. As shown in plot 2200D, the data 2200-1 includes a peak 2262-1 corresponding to the upper stop band edge within the passband 2211. Because this peak 2262-1 is both within the passband 2211 and of high amplitude, this may significantly negatively impact the performance of a multiplexer using filters corresponding to the passbands 2210 and 2211. However, as shown in FIG. 22, a filter with SAW resonators that include PZTs shifts this peak to peak 2262-2. The SAW resonators of the filter may be designed such that this peak 2262-2 lies between bands, such as between the frequency bands 2213 and 2214. In addition, the amplitude of the peak 2262-2 is significantly decreased compared to the amplitude of the peak 2262-1. In that regard, the signal quality of the filter that includes SAW resonators with PZTs is significantly increased.

Plot 2200E shows a conductance of a parallel resonator within a ladder filter. As shown in plot 2200D, the data 2200-1 includes a peak 2272-1. The peak 2272-1 may correspond to the upper stop band edge of the resonator without PZTs. In some cases, this peak 2272-1 may negatively impact the signal quality of the filter. However, as shown in FIG. 22, a filter with SAW resonators that include PZTs shifts this peak to peak 2272-2. The SAW resonators of the filter may be designed such that this peak 2272-2 lies between bands, such as between the frequency bands 2212 and 2213. In addition, the amplitude of the peak 2272-2 is significantly decreased compared to the amplitude of the peak 2272-1. In that regard, the signal quality of the filters and multiplexers that includes SAW resonators with PZTs is significantly increased.

Plot 2200F shows the absolute value of the admittance of a series resonator within a ladder filter. As shown in FIG. 22, the peak 2284-1 may be within the passband of the filter 2200-1 without PZTs. The peak 2284-2 may be within the passband of the filter 2200-2 with PZTs. As shown in plot 2200D, the data 2200-1 and 2200-2 both include an anti-resonance 2286. This anti-resonance 2286 may be aligned with the notch in filter transmission above the upper stop band edge 2236.

Plot 2200G shows the absolute value of the admittance of a parallel resonator within a ladder filter. Resonance frequencies (2294-1, 2294-2) and antiresonance frequencies (2296-1, 2296-2) correspond to the expected features in the transmission (2000A) and reflection (2200B) of the corresponding filter.

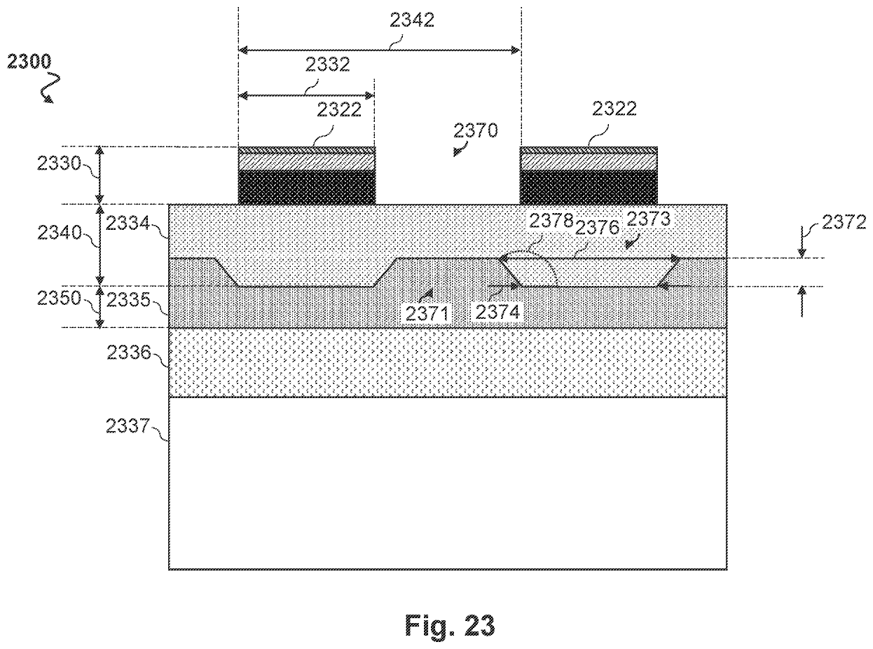

FIG. 23 is a cross-sectional side view of a SAW resonator 2300 with a piezoelectric trench 2371, according to aspects of the present disclosure. As shown in FIG. 23, a PZT may be configured according to any suitable geometry. For example, PZTs may be configured within an upper surface of the piezoelectric film of a SAW resonator or within a lower surface of the piezoelectric film of a SAW resonator or within both the upper and lower surfaces of the piezoelectric film of a SAW resonator.

The SAW resonator 2300 may be similar to the SAW resonators described previously. In particular, the SAW resonator 2300 may include a piezoelectric film 2334. The piezoelectric film 2334 may be similar to the piezoelectric films previously described. In some aspects, the piezoelectric film 2334 may be positioned on a dielectric layer 2335. The dielectric layer 2335 may be positioned on layers 2336 and 2337 as shown in FIG. 23. The SAW resonator 2300 may also include multiple electrodes 2322. The electrodes 2322 may be similar to the electrodes previously described.

The SAW resonator 2300 includes a PZT 2371. In the example shown in FIG. 23, the PZT 2371 may be a lower PZT, or a PZT formed within the lower surface of the piezoelectric film 2334. The PZT 2371 may be positioned between the electrodes 2322 as shown in FIG. 23. Similar lower PZTs may be positioned between other electrodes of the SAW resonator 2300. The PZT 2371 as well as any lower PZTs may be similar to any upper PZTs described herein. For example, lower PZTs may be of any suitable shape or size. In one aspect, the lower PZT 2371 may include tapered edges or shoulders. For example, the edges of the lower PZT 2371 may be tapered by the angle 2378 shown. In some aspects, a SAW resonator including lower PZTs, such as the lower PZT 2371, may alternatively be described as including dielectric trenches. For example, the SAW resonator 2300 includes a dielectric trench 2373. In some aspects, the dielectric trench 2373 may include edges angled at the angle 2378. In some aspects, the dielectric trench 2373 include an upper width 2376 and a lower width 2374. In some aspects, the dielectric trench 2371 and/or the lower piezoelectric trench 2371 may be of a depth 2372.

In the example shown in FIG. 23, the dielectric layer 2335 may be of a thickness 2350. The piezoelectric film 2334 may be of a thickness 2340. In some aspects, the electrodes 2322 may be of a thickness 2330. The width of the electrodes 2322 may be a width 2332 and the electrodes 2322 may be spaced according to a pitch 2342.

In the example shown in FIG. 23, the dielectric trenches may be aligned with the electrodes 2322. In other words, the dielectric trenches may be positioned beneath the electrodes 2322. Similarly, the lower PZTs, such as the lower PZT 2371 may be aligned with the gaps between the electrodes 2322, such as the gap 2370. In other words, the lower PZTs may be positioned under the gaps or spaces between the electrodes 2322.

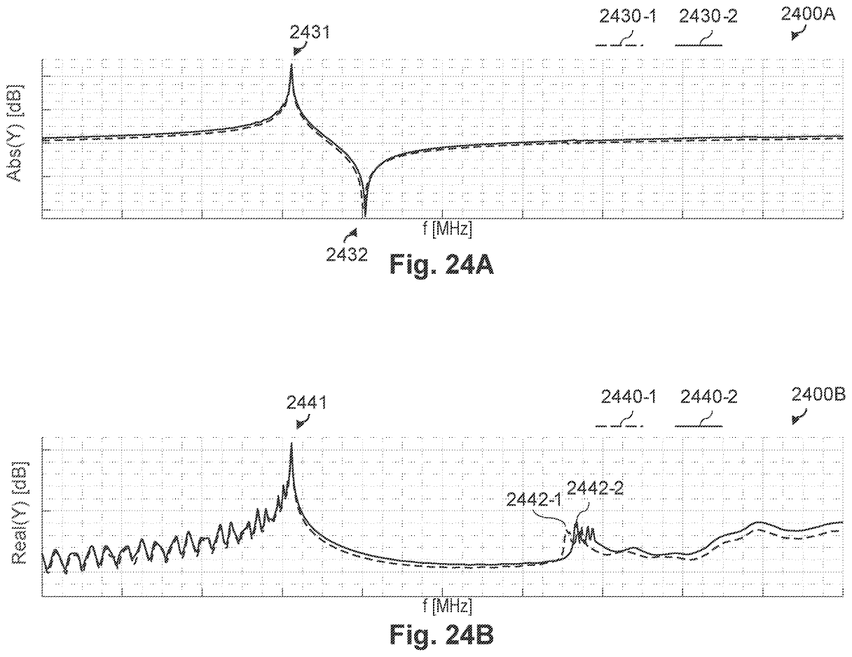

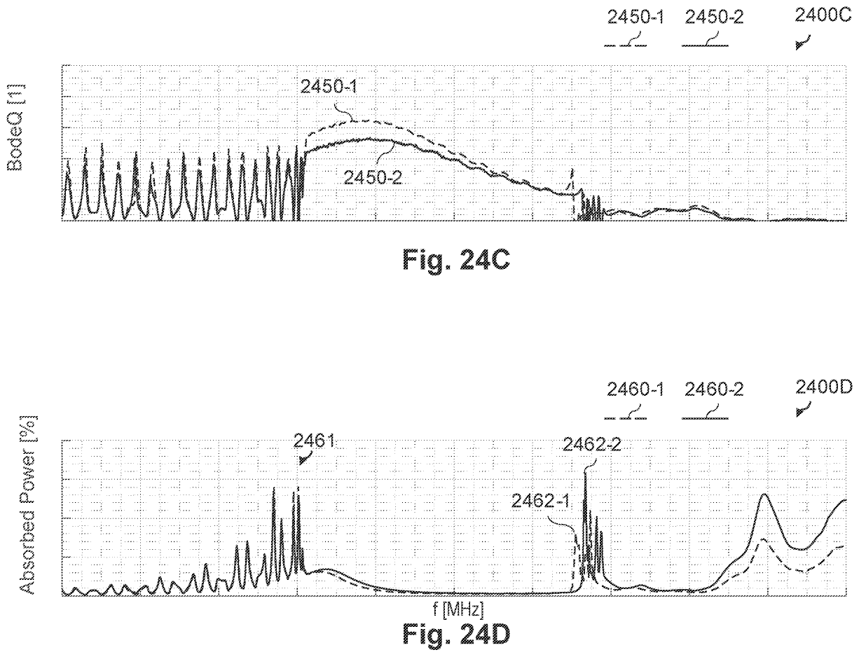

FIG. 24A is a graphical representation of the absolute value of the admittance of SAW resonators with piezoelectric trenches of different orientations, according to aspects of the present disclosure. In some aspects, the data shown in FIGS. 24A-24D may illustrates the benefits of a SAW resonator with lower PZTs to a SAW resonator with upper PZTs.

In some aspects, lower PZTs may be applied to series resonators but not parallel resonators. In some aspects, lower PZTs may be applied to parallel resonators but not series resonators. In some aspects, SAW resonators with upper PZTs and/or lower PZTs may be used as both parallel resonators and series resonators.

As shown, FIG. 24A includes a plot 2400A. The plot 2400A includes a data set 2430-1 and a data set 2430-2. In some aspects, the data set 2430-1 may be a data set corresponding to a frequency response of a SAW resonator with upper PZTs. The data set 2430-2 may be a data set corresponding to a frequency response of a SAW resonator with lower PZTs of the same shape and orientation but flipped.

As shown in FIG. 24A, each of the datasets 2430-1 and 2430-2 include a peak 2431 aligned about a fundamental frequency. Each of the datasets 2430-1 and 2430-2 also include an anti-resonance frequency 2432. As shown, the anti-resonance frequencies 2432 may not be aligned with one another but may be similar. This may result in a slight increase in coupling of the SAW resonator with lower PZTs compared to the coupling of the SAW resonator with upper PZTs. In some aspects, a SAW resonator with lower PZTs may exhibit a higher capacitance than a SAW resonator with upper PZTs. Larger coupling and larger capacitance are beneficial for improved performance and smaller size of the resulting resonators and filters.

FIG. 24B is a graphical representation of a conductance of SAW resonators with piezoelectric trenches of different orientations, according to aspects of the present disclosure. FIG. 24B includes a plot 2400B. The plot 2400B includes a data set 2440-1 and a data set 2440-2. In some aspects, the data set 2440-1 may be a data set corresponding to a frequency response of a SAW resonator with upper PZTs, such as the same SAW resonator corresponding to the data set 2430-1 of FIG. 24A. The data set 2440-2 may be a data set corresponding to the SAW resonator of the data set 2430-2, including a SAW resonator with lower PZTs.

Like the plot 2400A, the data sets of the plot 2400B are centered about the same fundamental frequency for comparison. As a result, the peak 2441 of each of the datasets 2440-1 and 2440-2 is aligned about the central frequency.

In some aspects, the data set 2440-1 includes a peak 2442-1. The peak 2442-1 may correspond to an upper stop band edge of SAW resonator with upper PZTs. The data set 2440-2 includes a peak 2442-2 corresponding to the upper stop band edge of a SAW resonator with lower PZTs. In this way, SAW resonators with lower PZTs may result in extending the upper stop band edge to a higher frequency than SAW resonators with upper PZTs which may be beneficial for improved performance.

FIG. 24C is a graphical representation of a quality factor of SAW resonators with piezoelectric trenches of different orientations, according to aspects of the present disclosure. FIG. 24C includes a plot 2400C. The plot 2400C includes a data set 2450-1 and a data set 2450-2. In some aspects, the data set 2450-1 may be a data set corresponding to a frequency response of a SAW resonator with upper PZTs, such as the same SAW resonator corresponding to the data set 2430-1 of FIG. 24A. The data set 2450-2 may be a data set corresponding to the SAW resonator with lower PZTs. As shown in FIG. 24C, the quality factor of the SAW resonator with upper PZTs may be greater than the quality factor the SAW resonator with lower PZTs. In that regard, the selection of using upper or lower PZTs may be a design choice.

FIG. 24D is a graphical representation of dissipated power of SAW resonators with piezoelectric trenches of different orientations, according to aspects of the present disclosure. FIG. 24D includes a plot 2400D. The plot 2400D includes a data set 2460-1 and a data set 2460-2. In some aspects, the data set 2460-1 may be a data set corresponding to a frequency response of a SAW resonator with upper PZTs, such as the same SAW resonator corresponding to the data sets 2430-1, 2440-1, and/or 2450-1. The data set 2460-2 may be a data set corresponding to the SAW resonator with lower PZTs, such as the SAW resonator of the data sets 2430-2, 2440-2, and/or 2450-2. In some aspects, the data sets 2460-1 and 2460-2 may each include a peak 2461. The data set 2460-1 may include a peak 2462-1. The data set 2460-2 shows that the peak 2462-2 of the data set 2460-2 is shifted higher in frequency than the peak 2462-1, both corresponding to the upper stop band edges of the resonators.

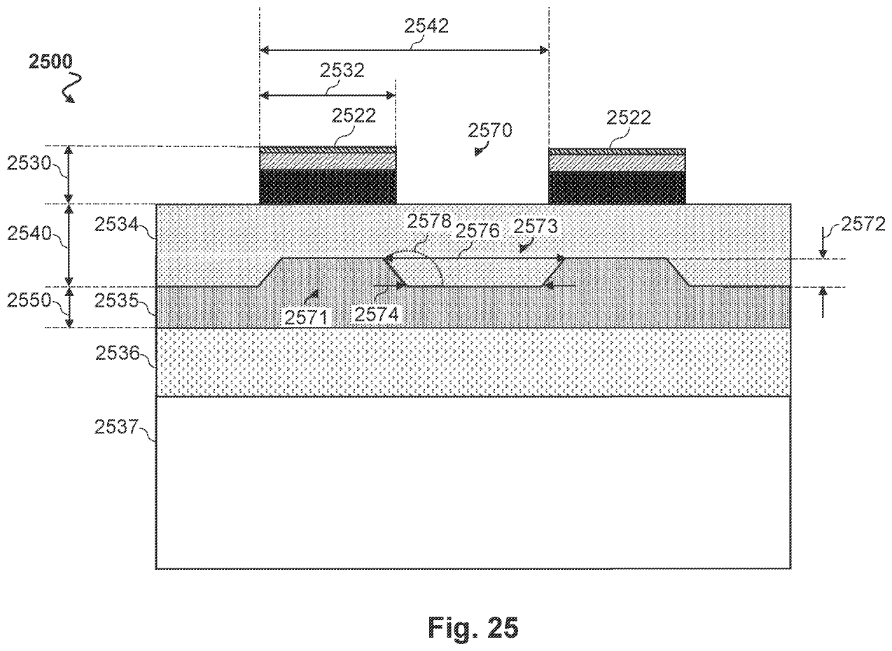

FIG. 25 is a cross-sectional side view of a SAW resonator with a piezoelectric trench, according to aspects of the present disclosure. As shown in FIG. 25, lower PZTs may be positioned in any suitable location relative to the electrodes of the SAW resonator device.

The SAW resonator 2500 may be similar to the SAW resonators described previously. In particular, the SAW resonator 2500 may include a piezoelectric film 2534. The piezoelectric film 2534 may be similar to the piezoelectric films previously described. In some aspects, the piezoelectric film 2534 may be positioned on a dielectric layer 2535. The dielectric layer 2535 may be positioned on layers 2536 and 2537 as shown in FIG. 25. The SAW resonator 2500 may also include multiple electrodes 2522. The electrodes 2522 may be similar to the electrodes previously described.

The SAW resonator 2500 includes a PZT 2571. In the example shown in FIG. 25, the PZT 1271 may be a lower PZT. The lower PZT 2571 may be positioned beneath the electrodes 2522 as shown in FIG. 25. In one aspect, the lower PZT 2571 may include tapered edges or shoulders. For example, the edges of the lower PZT 2571 may be tapered by the angle 2578 shown. In some aspects, a SAW resonator including lower PZTs, such as the lower PZT 2571, may alternatively be described as including dielectric trenches. For example, the SAW resonator 2500 includes a dielectric trench 2573. In some aspects, the dielectric trench 2573 may include edges angled at the angle 2578. In some aspects, the dielectric trench 2573 include an upper width 2576 and a lower width 2574. In some aspects, the dielectric trench 2573 and/or the lower piezoelectric trench 2571 may be of a depth 2572.

In the example shown in FIG. 25, the dielectric layer 2535 may be of a thickness 2550. The piezoelectric film 2534 may be of a thickness 2540. In some aspects, the electrodes 2522 may be of a width 2530. The width of the electrodes 2522 may be a width 2532 and the electrodes 2522 may be spaced according to a pitch 2542.

In the example shown in FIG. 25, the dielectric trenches may be positioned between the electrodes 2522 or be aligned with the gap 2570. Similarly, the lower PZTs, such as the lower PZT 2571 may be aligned with the electrodes 2522. In other words, the lower PZTs may be positioned under the electrodes 2522.

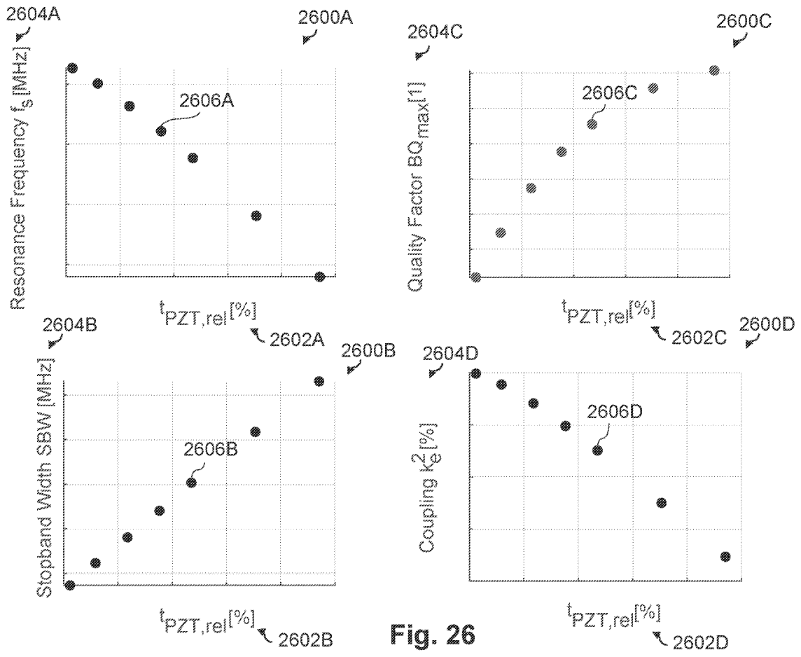

FIG. 26 is a graphical representation of a relationship between piezoelectric trench depth and SAW resonator performance, according to aspects of the present disclosure. The material of choice for this example may be lithium tantalate of a suitable orientation, as described earlier, such that mainly the shear horizontal acoustic mode is excited. The thickness may be thin enough to ensure a large coupling factor, large quality factor and suppressed spurious modes. The piezoelectric layer may be on suitable thin layers on top of a silicon wafer. Other choices of materials are possible, as described earlier. In some aspects, FIG. 26 includes a plot 2600A. The plot 2600A illustrates a relationship between piezoelectric trench depth and the resonance frequency of a SAW resonator. The plot 2600A includes an x-axis 2602A corresponding to trench depth and a y-axis 2604A corresponding to resonance frequency. Multiple data points 2606A are included within the plot 2600A.

FIG. 26 also includes a plot 2600B. The plot 2600B illustrates a relationship between piezoelectric trench depth and the resonance frequency of a SAW resonator. The plot 2600B includes an x-axis 2602B corresponding to trench depth and a y-axis 2604B corresponding to Stopband Width (SBW). Multiple data points 2606B are included within the plot 2600B.

FIG. 26 also includes a plot 2600C. The plot 2600C illustrates a relationship between piezoelectric trench depth and the resonance frequency of a SAW resonator. The plot 2600C includes an x-axis 2602C corresponding to trench depth and a y-axis 2604C corresponding to a maximum quality factor (BQmax). Multiple data points 2606C are included within the plot 2600C.

FIG. 26 also includes a plot 2600D. The plot 2600D illustrates a relationship between piezoelectric trench depth and the coupling coefficient of a SAW resonator. The plot 2600D includes an x-axis 2602D corresponding to trench depth and a y-axis 2604D corresponding to the coupling coefficient (k2e). Multiple data points 2606D are included within the plot 2600D.

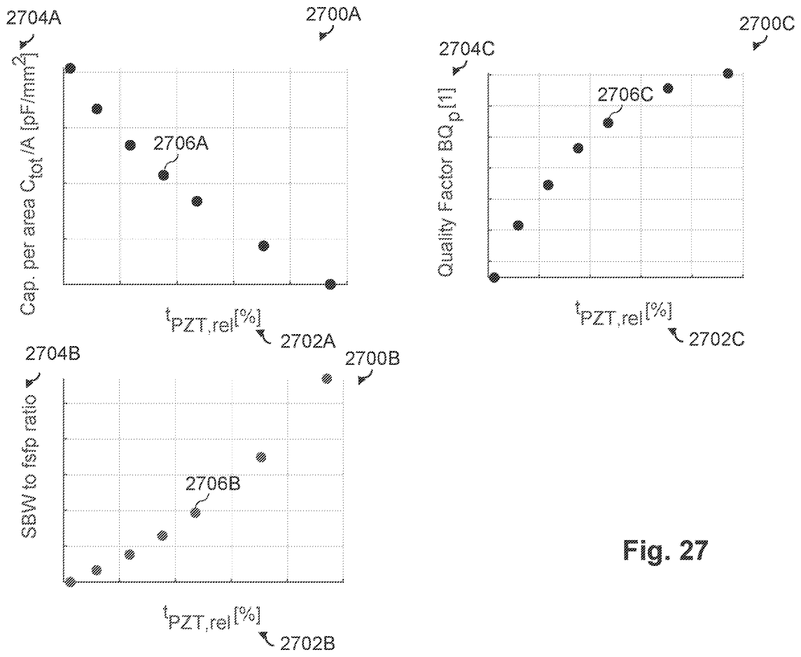

FIG. 27 is a graphical representation of a relationship between piezoelectric trench depth and SAW resonator performance, according to aspects of the present disclosure. In some aspects, FIG. 27 includes a plot 2700A. The plot 2700A illustrates a relationship between piezoelectric trench depth and the capacitance per area of a SAW resonator. The plot 2700A includes an x-axis 2702A corresponding to trench depth and a y-axis 2704A corresponding to capacitance per area. Multiple data points 2706A are included within the plot 2700A.

FIG. 27 also includes a plot 2700B. The plot 2700B illustrates a relationship between piezoelectric trench depth and the ratio between SBW and the frequency difference between resonance frequency fs and antiresonance frequency fp of a SAW resonator. The plot 2700B includes an x-axis 2702B corresponding to trench depth and a y-axis 2704B corresponding to ratio of SBW to fs/fp. Multiple data points 2706B are included within the plot 2700B. A large ratio beyond 2 implies that the USBE will be outside the passband. The lager the ratio, the larger the relative frequency region that will be within the resonator's stop band.

FIG. 27 also includes a plot 2700C. The plot 2700C illustrates a relationship between piezoelectric trench depth and quality factor of a SAW resonator at its antiresonance frequency. The plot 2700C includes an x-axis 2702C corresponding to trench depth and a y-axis 2704C corresponding to Quality Factor at antiresonance frequency (BQp). Multiple data points 2706C are included within the plot 2700C.

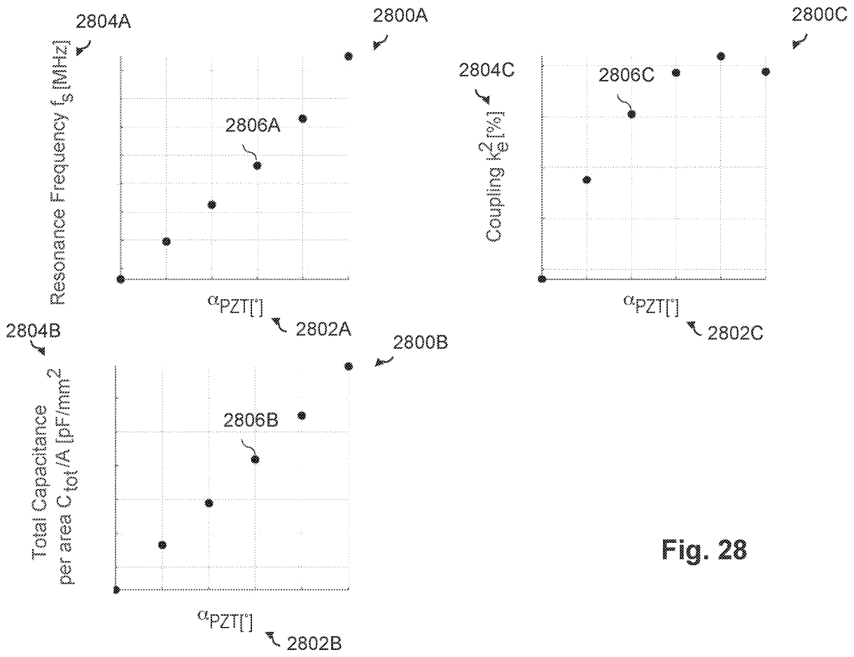

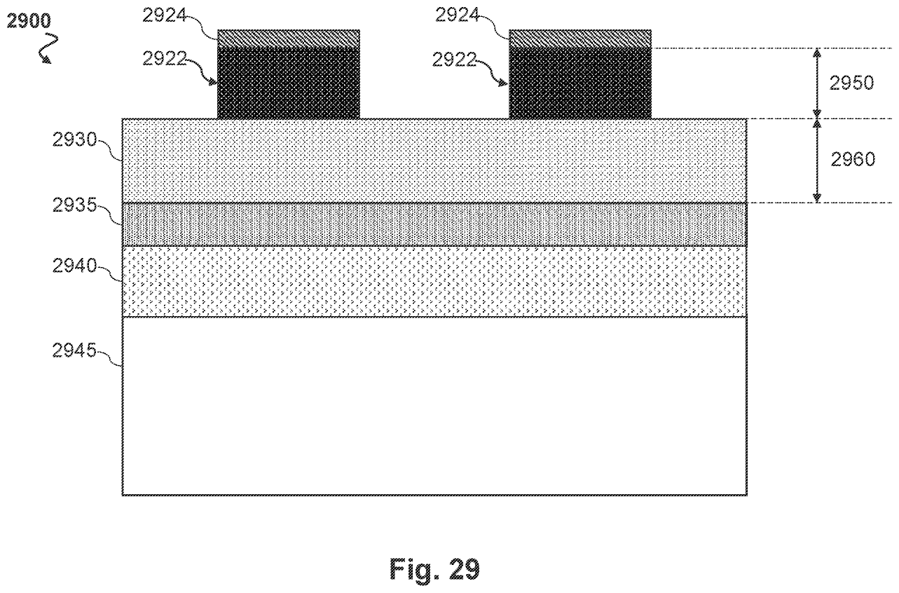

FIG. 28 is a graphical representation of a relationship between piezoelectric trench edge angle apzT (see e.g., angle 1178 of FIG. 11) and SAW resonator performance, according to aspects of the present disclosure. In some aspects, FIG. 28 includes a plot 2800A. The plot 2800A illustrates a relationship between an angle of edges of a piezoelectric trench and the resonance frequency of a SAW resonator. The angle of an edge of a piezoelectric trench may be shown by apzT in FIG. 28. The plot 2800A includes an x-axis 2802A corresponding to trench edge angle and a y-axis 2804A corresponding to resonance frequency. Multiple data points 2806A are included within the plot 2800A. Increasing the angle may increase the resonance frequency.

FIG. 28 also includes a plot 2800B. The plot 2800B illustrates a relationship between an angle of edges of a piezoelectric trench and the total capacitance per area of a SAW resonator. The plot 2800B includes an x-axis 2802B corresponding to trench edge angle and a y-axis 2804B corresponding to total capacitance per area. Multiple data points 2806B are included within the plot 2800B. Increasing the angle may increase the total capacitance per area.

FIG. 28 also includes a plot 2800C. The plot 2800C illustrates a relationship between an angle of edges of a piezoelectric trench and coupling of a SAW resonator. The plot 2800C includes an x-axis 2802C corresponding to trench edge angle and a y-axis 2804C corresponding to coupling. Multiple data points 2806C are included within the plot 2800C.

Increasing the angle may increase the coupling. The optimum angle in this regard maybe 120°.

FIG. 29 is a cross-sectional side view of a SAW resonator 2900 with sacrificial layers 2924 positioned over electrodes 2922, according to aspects of the present disclosure. In particular, the SAW resonator 2900 includes a piezoelectric film 2930. The piezoelectric film 2930 may be positioned on the dielectric layer 2935. In some aspects, the SAW resonator 2900 may also include layers 2940 and 2945 which may be similar to any of the layers described herein. The SAW resonator 2900 includes multiple electrodes 2922. A sacrificial layer 2924 may be positioned over each electrode 2922. In some aspects, the thickness of the electrode 2922 may be a thickness 2950 and a thickness of the piezoelectric film 2930 may be a thickness 2960. In some aspects, the SAW resonator 2900 may be a SAW resonator prior to a trim without PAS procedure using an ion beam or ion plasma. In some aspects, the SAW resonator 2900 may include the sacrificial layers 2924 to prevent material from the electrodes 2922 from being removed. In that regard, after a trim without PAS procedure, the electrodes 2922 of the SAW resonator 2900 may be of the same thickness 2950 but the piezoelectric film 2960 between the electrodes 2922 may be of a reduced thickness thus forming PZTs in the upper surface of the piezoelectric film 2930 without changing the thickness of the electrodes 2922.

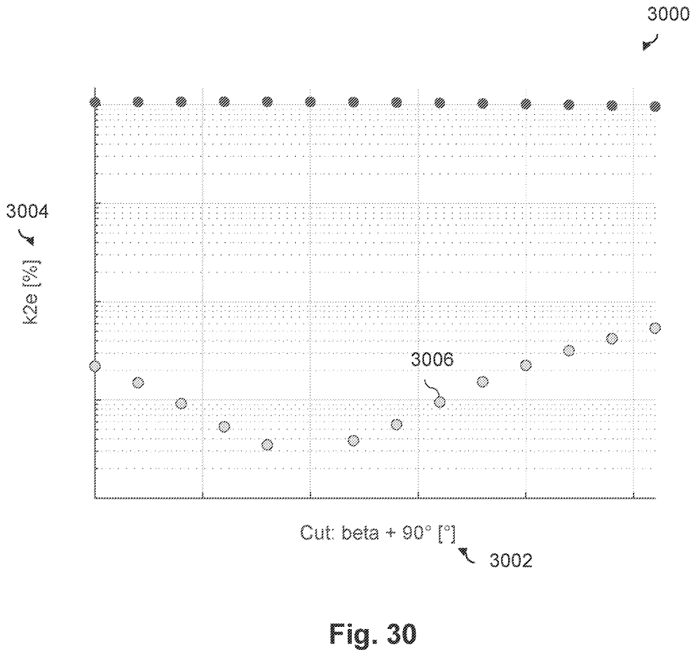

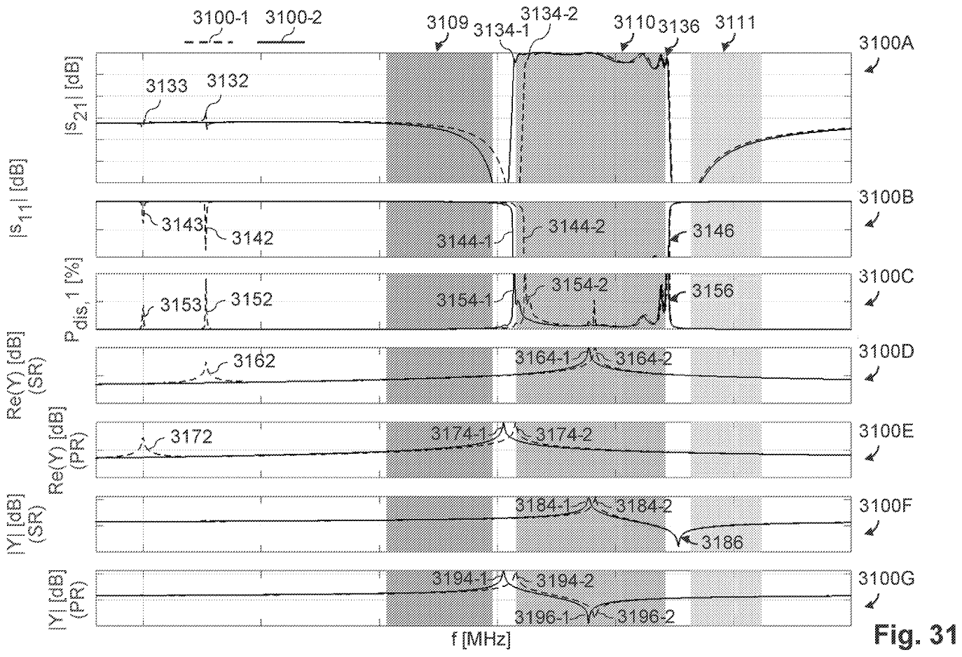

FIG. 30 is a graphical representation of a plot 3000 illustrating a relationship between piezoelectric cut 3002 and the effective coupling k2e 3004 of the main mode (Shear Mode SM) and a spurious mode (Rayleigh mode RM), according to aspects of the present disclosure. As shown in FIG. 30, the cut of the piezoelectric layer may alter the coupling to the spurious mode. Depending on the type and thickness of the piezoelectric layer, the material type of the substrate, the material type and thickness of intermediate layers, the depth of the PZT and other material and geometry factors a crystal orientation of minimized excitation of spurious modes can be found. For LT, orientations close to 30° Y-X can in some cases lead to minimized excitation of Rayleigh-type spurious acoustic modes while leading to a large coupling value for the shear main mode, while the coupling to main mode and spurious mode may vary as the crystal orientation (or cut) is varied. In some aspects, the optimized cut may vary depending on the particular attributes of the SAW resonator. For example, an optimized cut corresponding to a minimum spurious mode coupling may be greater or less than 30 degrees.

FIG. 31 is a graphical representation of a comparison of performance of SAW devices with piezoelectric trenches on a piezoelectric layer with optimized crystal orientation and on a piezoelectric layer with un-optimized crystal orientation, according to aspects of the present disclosure. FIG. 31 includes a plot 3100A. In some aspects, the plot 3100A corresponds to a comparison of the transmission of a filter, such as a ladder filter, including SAW resonators with piezoelectric trenches and optimized crystal orientation with a frequency response of a filter including SAW resonators with piezoelectric trenches and a crystal orientation that is not optimized. The plots include data 3100-1 corresponding to devices with piezoelectric trenches and optimized crystal orientation, as well as data 3100-2 corresponding to devices with piezoelectric trenches and a crystal orientation that is not optimized.

In some aspects, the piezoelectric crystal orientation of the filter corresponding to the data 3100-2 may be determined based on techniques described with reference to FIG. 30. In some aspects, the crystal orientation may be 30° Y-X. In some aspects, as shown in FIG. 31, this selection of the crystal orientation (sometimes referred to as the cut) may result in substantial suppression of a main spurious mode (such as the Rayleigh mode (“RM”)). This cut may also result in an excitation of a main mode (shear mode (“SM”)) that is stronger than for a typical standard cut. In some aspects, a device with piezoelectric trenches on a piezoelectric layer of a standard cut may be illustrated by the data 3100-1.

Each of the plots of FIG. 31 also highlight multiple frequency bands. For example, a band 3110 is shown corresponding to the passband of the filter. However, other bands highlighted may correspond to other filters within a multiplexer circuit or any other suitable circuit. These other bands include band 3109 and band 3111 in the example shown.

As shown in plot 3100A, the frequency response corresponding to the filter based on unoptimized piezoelectric crystal orientation includes a lower band edge 3134-2 and an upper band edge 3136. The frequency response corresponding to the filter based on optimized piezoelectric crystal orientation includes a lower band edge 3134-1 and an upper band edge 3136.

As also shown in the plot 3100A, the frequency response corresponding to the filter based on unoptimized piezoelectric crystal orientation includes spurious modes 3132 and 3133. The frequency response corresponding to the filter based on optimized piezoelectric crystal orientation does not exhibit these spurious modes, or these spurious modes are significantly suppressed.

The plot 3100B also illustrates the reflection coefficient corresponding to the filter based on unoptimized piezoelectric crystal orientation compared to the reflection coefficient corresponding to the filter based on optimized piezoelectric crystal orientation. A lower band edge 3144-1 may, for example, be aligned in frequency with the lower band edge 3134-1. Similarly, the lower band edge 3144-2 may be aligned in frequency with the lower band edge 3134-2. The upper band edge 3146 may be aligned with the upper band edge 3136. In addition, a peak 3142 is shown aligned with the spurious mode 3132 and a peak 3143 is shown aligned with the spurious mode 3133.

The plot 3100C also illustrates the dissipated power corresponding to the filter based on unoptimized piezoelectric crystal orientation compared to the dissipated power corresponding to the filter based on optimized piezoelectric crystal orientation. A spike in dissipated power 3154-1 may, for example, be aligned in frequency with the lower band edge 3134-1. Similarly, the spike in dissipated power 3154-2 may be aligned in frequency with the lower band edge 3134-2. The spike in dissipated power 3156 may be aligned with the upper band edge 3136. In addition, a peak in dissipated power 3152 is shown aligned with the spurious mode 3132. Similarly, a peak in dissipated power 3153 is shown aligned with the spurious mode 3133. As shown in the plots 3100B and 3100C, out-of-band content due to spurious modes is significantly reduced for the filter with SAW resonators with optimized PZTs using on optimized piezoelectric crystal orientation (3100-2).

Plot 3100D shows a conductance of a series resonator within a ladder filter. As shown in FIG. 31, a peak 3164-1 may be aligned with the center of the pass band of the unoptimized filter 3100-1. The peak 3164-2 may be aligned with the center of the pass band of the optimized filter 3100-2. As shown in plot 3100D, the data 3100-1 includes a peak 3162. This peak 3162 may negatively impact the performance of a multiplexer. However, as shown in the plots 3100B and 3100C, a filter with SAW resonators that include optimized PZTs using on optimized piezoelectric crystal orientation significantly reduce this peak.

Plot 3100E shows a conductance of a parallel resonator within a ladder filter. As shown in plot 3100E, the data 3100-1 includes a peak 3172. This peak 3172 may negatively impact the performance of a multiplexer. However, as shown in the plots 3100B and 3100C, a filter with SAW resonators that include optimized PZTs using on optimized piezoelectric crystal orientation significantly reduce this peak.

Plot 3100F shows the absolute value of the admittance of a series resonator within a ladder filter. As shown in FIG. 31, the peak 3184-1 may be aligned with the center of the pass band of the filter 3100-1. The peak 3184-2 may be aligned with the center of the pass band of the filter 3100-2. As shown in plot 3100D, the data 3100-1 and 3100-2 both include an anti-resonance 3186.

Plot 3100G shows the absolute value of the admittance of a parallel resonator within a ladder filter. The anti-resonance 3196-1 may be aligned with the center of the pass band of the filter 3100-1. The anti-resonance 3194-2 may be aligned with the center of the pass band of the filter 3100-2.

Aspects of the present invention include an embodiment including an acoustic wave resonator with a main mode with shear horizontal displacements and the piezoelectric thin film is made of lithium tantalate with a cut angle between 15 and 60 X-Y and a thickness of less than 5 lambda. In some embodiments, the piezoelectric film may be made of lithium tantalate with a cut angle between 20 and 42 X-Y and a thickness of less than 5 lambda. In some embodiments, the piezoelectric film may be made of lithium tantalate with a cut angle of 30 X-Y and a thickness of less than 5 lambda. In some embodiments, the piezoelectric film may be made of lithium tantalate with a cut angle of 30 X-Y and a thickness of less than 1 lambda. In some embodiments, the piezoelectric film may be made of lithium tantalate with a cut angle of 30 X-Y and a thickness between 5% and 60% of lambda. In some embodiments, the piezoelectric film may be made of lithium tantalate with a cut angle of 30 X-Y and a thickness between 10% and 50% of lambda. In some embodiments, the piezoelectric film may be made of lithium tantalate with a cut angle of 30 X-Y and a thickness between 15% and 30% of lambda. In some embodiments, the acoustic wave resonator includes a layer below the piezoelectric thin film, the layer being constructed of silicon oxide and of a thickness of less than 5 lambda. In some embodiments, the acoustic wave resonator includes a layer below the piezoelectric thin film, the layer being constructed of silicon oxide and of a thickness of less than 1 lambda. In some embodiments, the acoustic wave resonator includes a layer below the piezoelectric thin film, the layer being constructed of silicon oxide and of a thickness between 15% and 30% of lambda. While these ranges are provided herein for exemplary purposes, it is fully anticipated that the layers, including the piezoelectric thin layer as well as the layer beneath the piezoelectric thin layer may be of any suitable thickness and of any suitable angle or cut. In some embodiments, the acoustic wave resonator may include a substrate handle. In some embodiments, the substrate handle may be made of silicon, silicon carbide, quartz, sapphire, diamond, or any other material. In some aspects, lambda may represent a wavelength of motion, excitation, or acoustic energy of a wave corresponding to the acoustic wave resonator.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A surface acoustic wave (SAW) resonator device, comprising:
a first electrode positioned on an upper surface of a piezoelectric film;
a second electrode positioned on the upper surface of the piezoelectric film; and
a first piezoelectric trench (PZT) positioned between the first electrode and the second electrode, the first PZT including a recess in the piezoelectric film, the first PZT being of a first trench depth.

2. The SAW resonator device of claim 1, wherein the first PZT is an upper PZT formed within the upper surface of the piezoelectric film.

3. The SAW resonator device of claim 1, wherein the first PZT is a lower PZT formed within the lower surface of the piezoelectric film.

4. The SAW resonator device of claim 1, wherein the first trench depth of the first PZT is within a range of 0% and 100% of a thickness of the piezoelectric film.

5. The SAW resonator device of claim 4, wherein a trench depth of 100% corresponds to a fully-etched PZT.

6. The SAW resonator device of claim 1, wherein the first trench depth of the first PZT is within a range of 1 nm and 50 nm.

7. The SAW resonator device of claim 1, wherein the first PZT is centrally aligned between the first electrode and the second electrode.

8. The SAW resonator device of claim 1, wherein the piezoelectric film is positioned one or more dielectric layers positioned on a substrate.

9. The SAW resonator device of claim 1, wherein the first PZT includes a lower width corresponding to the width of the first PZT at the bottom of the PZT and an upper width corresponding to the width of the first PZT at the top of the first PZT.

10. The SAW resonator device of claim 9, wherein the upper width is greater than the lower width.

11. The SAW resonator device of claim 1, wherein the first PZT is symmetrical about an axis parallel to the first electrode.

12. The SAW resonator device of claim 1, wherein first PZT includes a first sloped region corresponding to a first angle and a second sloped region corresponding to a second angle.

13. The SAW resonator device of claim 1, further comprising a second PZT positioned within the piezoelectric film on a side of the first electrode opposite the first PZT such that a first piezoelectric plateau of a first width is formed between the first PZT and the second PZT; and a third PZT positioned within the piezoelectric film on a side of the second electrode opposite the first PZT such that a second piezoelectric plateau of a second width is formed between the first PZT and the third PZT.

14. The SAW resonator device of claim 13, wherein a width of the first electrode is equal to the first width of the first piezoelectric plateau.

15. The SAW resonator device of claim 13, wherein a width of the first electrode is less than the first width of the first piezoelectric plateau.

16. The SAW resonator device of claim 13, wherein a width of the first electrode is greater than the first width of the first piezoelectric plateau.

17. The SAW resonator device of claim 13, wherein the first electrode is centrally aligned with the first plateau.

18. The SAW resonator device of claim 1, wherein the piezoelectric film is positioned on a Bragg mirror.

19.-29. (canceled)

30. A surface acoustic wave (SAW) resonator device, comprising:
a plurality of electrodes positioned on an upper surface of a piezoelectric film of a first thickness; and
a plurality of piezoelectric trenches (PZTs) formed within the piezoelectric film between the plurality of electrodes, wherein the plurality of PZTs correspond to regions of the piezoelectric film of a second thickness less than the first thickness.

31.-33. (canceled)

34. A method of modifying a surface acoustic wave (SAW) resonator device, comprising:
receiving the SAW resonator device; and
applying an ion plasma to the upper surface of the SAW resonator device such that a thickness of one or more interdigital transducers is decreased and piezoelectric trenches are formed between the one or more interdigital transducers.

35.-47. (canceled)
